(19) United States
(12) Patent Application Publication
(10) Pub. No.: US 2013/0240875 A1
(43) Pub. Date: Sep. 19, 2013

(54) SEMICONDUCTOR DEVICE AND METHOD FOR MANUFACTURING THE SAME

(71) Applicant: SEMICONDUCTOR ENERGY LABORATORY CO., LTD., Atsugi-shi (JP)

(72) Inventors: Yuta Endo, Atsugi (JP); Kosei Noda, Atsugi (JP)

(73) Assignee: Semiconductor Energy Laboratory Co., Ltd., Atsugi-shi (JP)

(21) Appl. No.: 13/793,605

(22) Filed: Mar. 11, 2013

(30) Foreign Application Priority Data
Mar. 14, 2012 (JP) 2012-056798

(51) Int. Cl. H01L 29/786; H01L 29/66

(52) U.S. Cl. CPC H01L 29/78606; H01L 29/66969
USPC 257/43; 438/104

(57) ABSTRACT

A semiconductor device in which the parasitic resistance affected by a source and a drain is reduced and the parasitic capacitance is small is provided. The semiconductor device includes a pair of semiconductor layers; a semiconductor film in contact with each of the pair of semiconductor layers; a gate electrode overlapping with the semiconductor film and at least partly overlapping with the pair of semiconductor layers; and a gate insulating film between the semiconductor film and the gate electrode. A region which is in the pair of semiconductor layers and overlaps with the gate electrode and the semiconductor film has higher resistance than regions other than the region in the pair of semiconductor layers.

### BACKGROUND OF THE INVENTION

1. Field of the Invention

The present invention relates to a semiconductor device and a method for manufacturing the semiconductor device.

Note that in this specification, a semiconductor device refers to any device that can function by utilizing semiconductor characteristics, and an electro-optical device, a semiconductor circuit, an electronic device, and the like are all included in the category of semiconductor devices.

Note that the present invention relates to an object, a method, a manufacturing method, a process, a machine, a manufacture, or a composition of matter. In particular, the present invention relates to, for example, a semiconductor layer, a memory device, a display device, a liquid crystal display device, a light-emitting device, a driving method thereof, or a production method thereof. Further, the present invention relates to, for example, an electronic device including the semiconductor device, the display device, or the light-emitting device.

2. Description of the Related Art

Attention has been focused on a technique for forming a transistor using a semiconductor film formed over a substrate having an insulating surface. The transistor is applied to a wide range of semiconductor devices such as an integrated circuit and a display device. A silicon film or the like is known as a semiconductor film applicable to a transistor.

Whether an amorphous silicon film or a polycrystalline silicon film is used as a semiconductor film of a transistor depends on the purpose. For example, for a transistor in a large-sized display device, an amorphous silicon film is preferably used because a technique for forming a large-sized film has been established. On the other hand, for a transistor in a high-performance display device in which driver circuits are formed over one substrate, a polycrystalline silicon film is preferably used because the transistor can have high field-effect mobility. A polycrystalline silicon film can be formed by performing heat treatment at high temperature or laser beam treatment on an amorphous silicon film.

Further, there has been known a high-performance integrated circuit using an SOI (silicon on insulator) substrate in which a single crystal silicon film is provided over a silicon wafer with an oxide film therebetween.

Furthermore, in recent years, an oxide-based semiconductor film has attracted attention. For example, a transistor which includes an amorphous oxide semiconductor film containing indium, gallium, and zinc and having a carrier density less than 10¹⁸/cm³ is disclosed (see Patent Document 1).

An oxide semiconductor film can be formed by a sputtering method, and thus can be used for a transistor in a large-sized display device. Since a transistor including an oxide semiconductor film has high field-effect mobility, the use of such a transistor can achieve a high-performance display device or integrated circuit in which driver circuits are formed over one substrate. In addition, there is an advantage that capital investment can be reduced because part of production equipment for a transistor including an amorphous silicon film can be retrofitted and utilized.

With an increase in size and an increase in degree of integration of a semiconductor device, the influence of parasitic capacitance between wirings of transistors becomes large. For example, when source and drain regions are formed in a self-aligned manner with the use of a gate electrode, the parasitic capacitance between the gate electrode and the source and drain regions can be reduced.

A technique for providing source and drain regions in a self-aligned manner in a transistor including an oxide semiconductor film is disclosed (see Patent Document 2). Patent Document 2 discloses that a gate insulating film and a gate electrode having the same shape are formed in this order over a channel region of an oxide semiconductor film, and a metal film is formed over the oxide semiconductor film, the gate insulating film, and the gate electrode. Then, the metal film is oxidized by heat treatment to form a high-resistance film and to form a low-resistance region in at least part of the source and drain regions in the depth direction from the top surface of the source and drain regions.

### REFERENCE

### Patent Documents

[Patent Document 1] Japanese Published Patent Application No. 2006-165528
[Patent Document 2] Japanese Published Patent Application No. 2011-228622

### SUMMARY OF THE INVENTION

However, when the source and drain regions are formed by reducing the resistance of the semiconductor film itself, parasitic resistance cannot be made sufficiently low depending on the kind of semiconductor film. In view of this, an object is to provide a semiconductor device in which the parasitic resistance related to a source and a drain is reduced and parasitic capacitance is low regardless of the kind of semiconductor film. Another object is to reduce the parasitic resistance related to a source and a drain. Another object is to provide a semiconductor device with small parasitic capacitance.

Another object is to suppress a reduction in luminance. Another object is to reduce power consumption. Another object is to suppress a reduction in lifetime. Another object is to suppress a temperature increase. Another object is to improve a manufacturing yield. Another object is to reduce cost. Another object is to improve image quality. Another object is to provide a novel semiconductor device. Another object is to provide an excellent semiconductor device.

Note that the descriptions of these objects do not preclude the existence of other objects. Note that one embodiment of the present invention does not necessarily achieve all the objects listed above. Other objects will be apparent from and can be derived from the description of the specification, the drawings, the claims, and the like.

A semiconductor device according to one embodiment of the present invention includes a pair of semiconductor layers; a semiconductor film in contact with each of the pair of semiconductor layers; a gate electrode overlapping with the semiconductor film and at least partly overlapping with the pair of semiconductor layers; and a gate insulating film between the semiconductor film and the gate electrode. A region which is in the pair of semiconductor layers and overlaps with the gate electrode and the semiconductor film has higher resistance than regions other than the region in the pair of semiconductor layers.

A semiconductor device according to one embodiment of the present invention includes a semiconductor film; a gate insulating film over the semiconductor film; a gate electrode overlapping with the semiconductor film, over the gate insulating film; and a pair of semiconductor layers each of which is in contact with the semiconductor film and which at least partly overlaps with the gate electrode. A region which is in the pair of semiconductor layers and overlaps with the gate electrode and the semiconductor film has higher resistance than regions other than the region in the pair of semiconductor layers.

The semiconductor device according to one embodiment of the present invention includes a first electrode electrically connected to one of the pair of semiconductor layers; and a display element over the first electrode.

The semiconductor device according to one embodiment of the present invention further includes a second electrode formed through the same steps as the one of the pair of semiconductor layers. The second electrode at least partly overlaps with the first electrode with an insulating film between the second electrode and the first electrode.

The composition of a semiconductor contained in the pair of semiconductor layers is different from that of a semiconductor contained in the semiconductor film. For example, the pair of semiconductor layers contains silicon, germanium, zinc oxide, indium oxide, or tin oxide.

In order to make the region which is in the pair of semiconductor layers and overlaps with the gate electrode and the semiconductor film have higher resistance than the other regions in the pair of semiconductor layers (make regions other than the region which is in the pair of semiconductor layers and overlaps with the gate electrode and the semiconductor film have lower resistance than the region), for example, the other regions in the pair of semiconductor layers may contain an impurity generating a carrier in the pair of semiconductor layers at higher concentration than the region.

Specifically, in the case where the pair of semiconductor layers contains a Group 14 element such as silicon or germanium, a trivalent element (boron, aluminum, gallium, indium, or the like) or a pentavalent element (phosphorus, arsenic, antimony, or the like) may be used as the impurity generating a carrier in the pair of semiconductor layers. Note that when the semiconductor film is an n-type semiconductor film, a pentavalent element is preferably used as the impurity; when the semiconductor film is a p-type semiconductor film, a trivalent element is preferably used as the impurity.

In the case where the pair of semiconductor layers contains zinc oxide, a trivalent element (aluminum, gallium, indium, or the like) may be used as the impurity. In the case where the pair of semiconductor layers contains indium oxide, a quadrivalent element (tin, titanium, zirconium, hafnium, cerium, or the like) may be used as the impurity. In the case where the pair of semiconductor layers contains tin oxide, fluorine, antimony, or the like may be used as the impurity.

As described above, the region which is in the pair of semiconductor layers and to which the impurity is added can serve as a low-resistance region. For example, by addition of the impurity to the pair of semiconductor layers with the gate electrode used as a mask, a region which is in the pair of semiconductor layers and does not overlap with the gate electrode can serve as a low-resistance region. Further, a region which is in the pair of semiconductor layers and overlaps with the gate electrode can serve as a relatively high-resistance region. With such a method, the low-resistance region can be extended to the vicinity of a channel region; thus, the parasitic resistance related to the source and the drain can be made low. Further, since the gate electrode and the low-resistance region do not overlap with each other, the parasitic capacitance of the semiconductor device can be made small.

The resistance of a region to be the low-resistance region can be easily reduced and the resistivity of the region to be the low-resistance region can be easily controlled by forming the low-resistance region in this manner. Therefore, the low-resistance region can function as a source electrode, a drain electrode, or a lightly doped drain (LDD) region of the transistor.

According to one embodiment of the present invention, the design flexibility of a semiconductor device can be improved. For example, the number of choices of a semiconductor film including a channel region in a transistor can be increased. That is, even in the case where it is difficult to make the resistance of the semiconductor film low, low-resistance regions in a pair of semiconductor layers can function as a source electrode and a drain electrode; thus, the source electrode and the drain electrode of a transistor can be formed in a self-aligned manner. The regions functioning as the source region and the drain region are formed in a self-aligned manner as described above; thus, parasitic capacitance is not generated, and in addition, an offset region or LDD region can be provided in a desired region as appropriate.

With the use of a pair of semiconductor layers in which low-resistance regions are provided in a self-aligned manner, a transistor in which the parasitic resistance related to a source and a drain is reduced and the parasitic capacitance is small can be provided. Further, a semiconductor device including the transistor can be provided. Furthermore, the parasitic capacitance related to a source and a drain can be reduced. Further, a semiconductor device with small parasitic capacitance can be provided.

A reduction in luminance can be suppressed. Power consumption can be reduced. A reduction in lifetime can be suppressed. A temperature increase can be suppressed. A manufacturing yield can be improved. Cost can be reduced. Image quality can be improved. A novel semiconductor device can be provided. An excellent semiconductor device can be provided.

### BRIEF DESCRIPTION OF THE DRAWINGS

FIGS. 1A to 1C are a top view and cross-sectional views illustrating an example of a transistor according to one embodiment of the present invention.

FIGS. 2A to 2C are a top view and cross-sectional views illustrating an example of a transistor according to one embodiment of the present invention.

FIGS. 3A to 3C are a top view and cross-sectional views illustrating an example of a transistor according to one embodiment of the present invention.

FIGS. 4A to 4C are a top view and cross-sectional views illustrating an example of a transistor according to one embodiment of the present invention.

FIGS. 5A to 5D are cross-sectional views illustrating an example of a method for manufacturing the transistor illustrated in FIGS. 1A to 1C.

FIGS. 6A to 6C are cross-sectional views illustrating the example of the method for manufacturing the transistor illustrated in FIGS. 1A to 1C.

FIGS. 7A to 7D are cross-sectional views illustrating an example of a method for manufacturing the transistor illustrated in FIGS. 2A to 2C.

FIGS. 8A to 8D are cross-sectional views illustrating the example of the method for manufacturing the transistor illustrated in FIGS. 2A to 2C.

FIGS. 9A to 9D are cross-sectional views illustrating an example of a method for manufacturing the transistor illustrated in FIGS. 3A to 3C.

FIGS. 10A to 10D are cross-sectional views illustrating the example of the method for manufacturing the transistor illustrated in FIGS. 3A to 3C.

FIGS. 11A to 11D are cross-sectional views illustrating an example of a method for manufacturing the transistor illustrated in FIGS. 4A to 4C.

FIGS. 12A to 12C are cross-sectional views illustrating the example of the method for manufacturing the transistor illustrated in FIGS. 4A to 4C.

FIGS. 13A and 13B are a circuit diagram and a cross-sectional view of part of a pixel of a display device using an EL element, according to one embodiment of the present invention, and FIG. 13C is a cross-sectional view of a light-emitting layer in the display device.

FIGS. 14A and 14B are each a cross-sectional view of part of a pixel of a display device using an EL element, according to one embodiment of the present invention.

FIGS. 15A and 15B are a circuit diagram and a cross-sectional view of a pixel of a display device using a liquid crystal element, according to one embodiment of the present invention.

FIGS. 16A and 16B are each a cross-sectional view of a pixel of a display device using a liquid crystal element, according to one embodiment of the present invention.

FIGS. 17A and 17B are circuit diagrams of a semiconductor device according to one embodiment of the present invention, FIG. 17C is a cross-sectional view thereof, and FIG. 17D is a graph showing electric characteristics thereof.

FIG. 18A is a circuit diagram of a semiconductor device according to one embodiment of the present invention, FIG. 18B is a graph showing electric characteristics thereof, and FIG. 18C is a cross-sectional view thereof.

FIGS. 19A to 19C are block diagrams illustrating structures of a CPU according to one embodiment of the present invention.

FIGS. 20A to 20D each illustrate an electronic device according to one embodiment of the present invention.

### DETAILED DESCRIPTION OF THE INVENTION

Embodiments of the present invention will be described in detail with reference to the accompanying drawings. Note that the present invention is not limited to the description below, and it is easily understood by those skilled in the art that modes and details disclosed herein can be modified in various ways. Further, the present invention is not construed as being limited to the description of the embodiments below. In describing structures of the present invention with reference to the drawings, the same reference numerals are used in common for the same portions in different drawings. The same hatching pattern is applied to similar parts, and the similar parts are not especially denoted by reference numerals in some cases.

Note that what is described (or part thereof) in one embodiment can be applied to, combined with, or exchanged with another content in the same embodiment and/or what is described (or part thereof) in another embodiment or other embodiments.

Note that in each embodiment, a content described in the embodiment is a content described with reference to a variety of diagrams or a content described with texts described in this specification.

In addition, by combining a diagram (or part thereof) described in one embodiment with another part of the diagram, a different diagram (or part thereof) described in the same embodiment, and/or a diagram (or part thereof) described in one or a plurality of different embodiments, much more diagrams can be formed.

Note that the size, the thickness of a layer, or a region in diagrams is sometimes exaggerated for simplicity. Therefore, embodiments of the present invention are not limited to such scales.

Note that diagrams are perspective views of ideal examples, and shapes or values are not limited to those illustrated in the diagrams. For example, the following can be included: variation in shape due to a manufacturing technique or dimensional deviation; or variation in signal, voltage, or current due to noise or difference in timing.

Note that a voltage refers to a potential difference between a certain potential and a reference potential (e.g., a ground potential (GND) or a source potential) in many cases. Accordingly, a voltage can also be called a potential.

Further, even when the expression “to be electrically connected” is used in this specification, there is a case in which no physical connection is made and a wiring is just extended in an actual circuit.

Note that, when two or more layers are processed and formed from one layer, these layers are defined as existing in the same layer. For example, when a layer is formed and then subjected to etching and so on to produce a layer A and a layer B, they are regarded as the layers existing in the same layer.

Note that technical terms are used in order to describe a specific embodiment, example, or the like in many cases. One embodiment of the present invention should not be construed as being limited by the technical terms.

Terms which are not defined in this specification (including terms used for science and technology, such as technical terms or academic terms) can be used as the terms having meaning equal to general meaning that an ordinary person skilled in the art understands. It is preferable that terms defined by dictionaries or the like be construed to have meanings consistent with the background of related art.

Note that the ordinal numbers such as “first” and “second” in this specification are used for convenience and do not denote the order of steps or the stacking order of layers. In addition, the ordinal numbers in this specification do not denote particular names which specify the present invention.

Note that a content which is not specified in any drawing or text in the specification can be excluded from the invention. When the number range of values indicated by e.g., the maximum value and the minimum value is described, the range may be freely narrowed or a value in the range may be excluded, so that the invention can be specified by a range resulting from exclusion of part of the range. In this manner, it is possible to specify the technical scope of the present invention so that a conventional technology is excluded, for example.

Specifically, for example, a diagram of a circuit including first to fifth transistors is described. In that case, it can be specified that the circuit does not include a sixth transistor in the invention. It can be specified that the circuit does not include a capacitor in the invention. It can be specified that the circuit does not include a sixth transistor with a particular connection structure in the invention. It can be specified that the circuit does not include a capacitor with a particular connection structure in the invention. For example, it can be specified that a sixth transistor whose gate is connected to a gate of the third transistor is not included in the invention. For example, it can be specified that a capacitor whose first electrode is connected to the gate of the third transistor is not included in the invention.

As another specific example, a description of a value, “a voltage is preferably higher than or equal to 3 V and lower than or equal to 10 V” is given. In that case, for example, it can be specified that the case where the voltage is higher than or equal to −2 V and lower than or equal to 1 V is excluded from the invention. For example, it can be specified that the case where the voltage is higher than or equal to 13 V is excluded from the invention. Note that, for example, it can be specified that the voltage is higher than or equal to 5 V and lower than or equal to 8 V in the invention. Note that, for example, it can be specified that the voltage is approximately 9 V in the invention. Note that, for example, it can be specified that the voltage is higher than or equal to 3 V and lower than or equal to 10 V but is not 9 V in the invention.

As another specific example, a description of a value, “a voltage is preferably 10 V” is given. In that case, for example, it can be specified that the case where the voltage is higher than or equal to −2 V and lower than or equal to 1 V is excluded from the invention. For example, it can be specified that the case where the voltage is higher than or equal to 13 V is excluded from the invention.

As another specific example, a description of a property of a material, “a film is an insulating film”, is given. In that case, for example, it can be specified that the case where the insulating film is an organic insulating film is excluded from the invention. For example, it can be specified that the case where the insulating film is an inorganic insulating film is excluded from the invention.

As another specific example, a description of a stacked structure, “a film is provided between A and B” is given. In that case, for example, it can be specified that the case where the film is a stacked film of four or more layers is excluded from the invention. For example, it can be specified that the case where a conductive film is provided between A and the film is excluded from the invention.

Note that various people can implement the invention described in this specification and the like. However, different people may be involved in the implementation of the invention. For example, in the case of a transmission/reception system, the following case is possible: Company A manufactures and sells transmitting devices, and Company B manufactures and sells receiving devices. As another example, in the case of a light-emitting device including a TFT and a light-emitting element, the following case is possible: Company A manufactures and sells semiconductor devices including TFTs, and Company B purchases the semiconductor devices, provides light-emitting elements for the semiconductor devices, and completes light-emitting devices.

In such a case, one embodiment of the invention can be constituted so that a patent infringement can be claimed against each of Company A and Company B. That is, one embodiment of the invention with which a patent infringement suit can be filed against Company A or Company B is clear and can be regarded as being disclosed in this specification or the like. For example, in the case of a transmission/reception system, one embodiment of the invention can be constituted by only a transmitting device and one embodiment of the invention can be constituted by only a receiving device. Those embodiments of the invention are clear and can be regarded as being disclosed in this specification or the like. As another example, in the case of a light-emitting device including a TFT and a light-emitting element, one embodiment of the invention can be constituted by only a semiconductor device including a TFT, and one embodiment of the invention can be constituted by only a light-emitting device including a TFT and a light-emitting element. Those embodiments of the invention are clear and can be regarded as being disclosed in this specification or the like.

### Embodiment 1

In this embodiment, a transistor according to one embodiment of the present invention will be described.

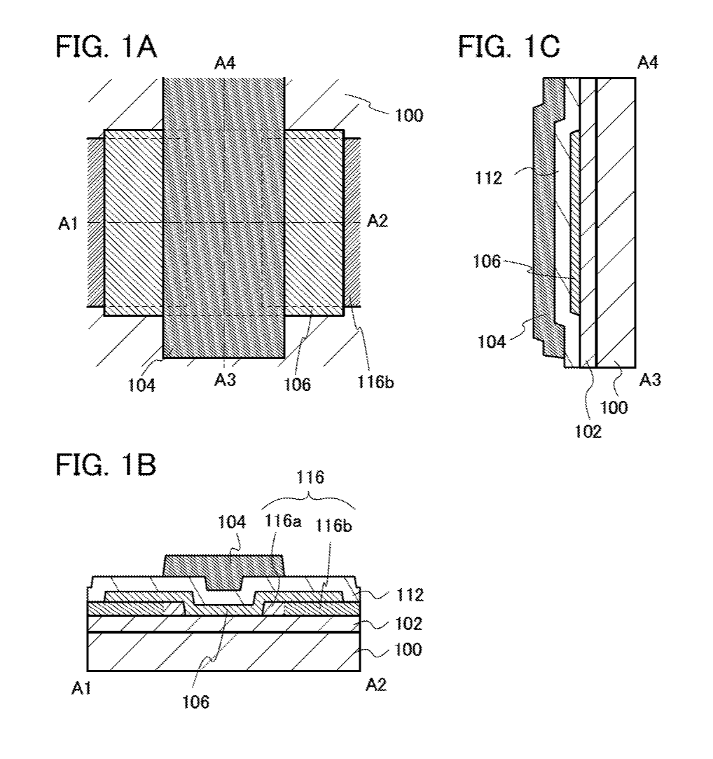

FIG. 1A is a top view of a transistor according to one embodiment of the present invention. FIG. 1B is a cross-sectional view taken along dashed-dotted line A1-A2 in FIG. 1A. FIG. 1C is a cross-sectional view taken along dashed-dotted line A3-A4 in FIG. 1A. Note that a gate insulating film 112 and the like are not illustrated in FIG. 1A for easy understanding.

FIG. 1B is a cross-sectional view of the transistor including a base insulating film 102 over a substrate 100; a pair of semiconductor layers 116 each including a region 116a and a region 116b, over the base insulating film 102; a semiconductor film 106 over the base insulating film 102 and the pair of semiconductor layers 116; the gate insulating film 112 over the semiconductor film 106; and a gate electrode 104 overlapping with the semiconductor film 106, over the gate insulating film 112.

In the pair of semiconductor layers 116, the regions 116a overlap with the gate electrode 104. The regions 116b do not overlap with the gate electrode 104.

The pair of semiconductor layers 116 contains silicon, germanium, zinc oxide, indium oxide, or tin oxide.

In the pair of semiconductor layers 116, the regions 116b are each a low-resistance region. On the other hand, the regions 116a are each a high-resistance region. That is, the regions 116b have lower resistance than the regions 116a. Note that in this specification, a “low-resistance region” refers to a region having a resistivity higher than or equal to 1 μΩcm and lower than or equal to 100 μΩcm or higher than or equal to 100 μΩcm and lower than or equal to 1 μΩcm. Further, in this specification, a “high-resistance region” refers to a region having a resistivity higher than 100 μΩcm or higher than 1 μΩcm.

In the pair of semiconductor layers 116, the regions 116b are each a region which contains impurities generating carriers in the pair of semiconductor layers 116. The regions 116a are each a region which does not contain impurities generating carriers in the pair of semiconductor layers 116. Note that, in this specification, a “region which contains impurities generating carriers” refers to a region whose concentration of impurities generating carriers is higher than or equal to 1×10¹⁴ atoms/cm³ and lower than or equal to 1×10²² atoms/cm³, or higher than or equal to 1×10¹⁶ atoms/cm³ and lower than or equal to 1×10²¹ atoms/cm³. Further, in this specification, a “region which does not contain impurities generating carriers” refers to a region whose concentration of impurities generating carriers is lower than 1×10¹⁴ atoms/cm³ or lower than 1×10¹⁶ atoms/cm³.

In the case where the pair of semiconductor layers 116 contains a Group 14 element such as silicon or germanium, the regions 116b contain a trivalent element (boron, aluminum, gallium, indium, or the like) or a pentavalent element (phosphorus, arsenic, antimony, or the like).

Further, in the case where the pair of semiconductor layers 116 contains zinc oxide, the regions 116b contain a trivalent element (aluminum, gallium, indium, or the like). In the case where the pair of semiconductor layers 116 contains indium oxide, the regions 116b contain a quadrivalent element (tin, titanium, zirconium, hafnium, cerium, or the like). In the case where the pair of semiconductor layers 116 contains tin oxide, the regions 116b contain fluorine, antimony, or the like.

The gate electrode 104 does not overlap with the regions 116b as described above, whereby the parasitic capacitance of the transistor in FIGS. 1A to 1C is small.

The regions 116b of the pair of semiconductor layers 116 function as a source electrode and a drain electrode of the transistor. The regions 116b functioning as the source electrode and the drain electrode are extended to the vicinity of a channel region (a region overlapping with the gate electrode 104, in the semiconductor film 106), whereby the parasitic resistance of the transistor in FIGS. 1A to 1C can be made lower and the parasitic capacitance thereof can be made smaller.

As the semiconductor film 106, an organic semiconductor film or an oxide semiconductor film may be used, for example.

Specifically, as the oxide semiconductor film, an In—M—Zn oxide film may be used. Here, a metal element M is an element whose bond energy with oxygen is higher than that of In and that of Zn. Alternatively, the metal element M is an element which has a function of suppressing desorption of oxygen from the In—M—Zn oxide film. Owing to the effect of the metal element M, generation of oxygen vacancies in the oxide semiconductor film is suppressed. Note that oxygen vacancies in the oxide semiconductor film generate carriers in some cases. Therefore, the effect of the metal element M suppresses an increase in off-state current due to an increase in the carrier density of the oxide semiconductor film. Furthermore, a change in the electric characteristics of the transistor, which is caused by oxygen vacancies, can be reduced, whereby a highly reliable transistor can be obtained.

Specifically, the metal element M may be Al, Sc, Ti, V, Cr, Mn, Fe, Co, Ni, Ga, Y, Zr, Nb, Mo, Sn, La, Ce, Pr, Nd, Sm, Eu, Gd, Tb, Dy, Ho, Er, Tm, Yb, Lu, Hf, Ta, or W, and is preferably Al, Ti, Ga, Y, Zr, Ce, or Hf. For the metal element M, one or more elements may be selected from the above elements. Further, Si or Ge may be used instead of the metal element M.

The hydrogen concentration in the oxide semiconductor film is 2×10²⁰ atoms/cm³ or lower, preferably 5×10¹⁹ atoms/cm³ or lower, more preferably 1×10¹⁹ atoms/cm³ or lower. This is because hydrogen in the oxide semiconductor film generates unintentional carriers in some cases. The generated carriers might increase the off-state current of the transistor and vary the electric characteristics of the transistor. Thus, when the hydrogen concentration in the oxide semiconductor film is in the above range, an increase in the off-state current of the transistor and a change in the electric characteristics of the transistor can be suppressed.

An oxide semiconductor film may be in a non-single-crystal state, for example. The non-single-crystal state is, for example, structured by at least one of c-axis aligned crystal (CAAC), polycrystal, microcrystal, and an amorphous part. The density of defect states of an amorphous part is higher than those of microcrystal and CAAC. The density of defect states of microcrystal is higher than that of CAAC. Note that an oxide semiconductor including CAAC is referred to as a CAAC-OS (c-axis aligned crystalline oxide semiconductor).

For example, an oxide semiconductor film may include a CAAC-OS. In the CAAC-OS, for example, c-axes are aligned, and a-axes and/or b-axes are not macroscopically aligned.

For example, an oxide semiconductor film may include microcrystal. Note that an oxide semiconductor including microcrystal is referred to as a microcrystalline oxide semiconductor. A microcrystalline oxide semiconductor film includes microcrystal (also referred to as nanocrystal) with a size greater than or equal to 1 nm and less than 10 nm, for example. Alternatively, a microcrystalline oxide semiconductor film, for example, includes a crystal-amorphous mixed phase structure where crystal parts (each of which is greater than or equal to 1 nm and less than 10 nm) are distributed.

For example, an oxide semiconductor film may include an amorphous part. Note that an oxide semiconductor including an amorphous part is referred to as an amorphous oxide semiconductor. An amorphous oxide semiconductor film, for example, has disordered atomic arrangement and no crystalline component. Alternatively, an amorphous oxide semiconductor film is, for example, absolutely amorphous and has no crystal part.

Note that an oxide semiconductor film may be a mixed film including any of a CAAC-OS, a microcrystalline oxide semiconductor, and an amorphous oxide semiconductor. The mixed film, for example, includes a region of an amorphous oxide semiconductor, a region of a microcrystalline oxide semiconductor, and a region of a CAAC-OS. Further, the mixed film may have a stacked structure including a region of an amorphous oxide semiconductor, a region of a microcrystalline oxide semiconductor, and a region of a CAAC-OS, for example.

Note that an oxide semiconductor film may be in a single-crystal state, for example.

An oxide semiconductor film preferably includes a plurality of crystal parts. In each of the crystal parts, a c-axis is preferably aligned in a direction parallel to a normal vector of a surface where the oxide semiconductor film is formed or a normal vector of a surface of the oxide semiconductor film. Note that, among crystal parts, the directions of the a-axis and the b-axis of one crystal part may be different from those of another crystal part. An example of such an oxide semiconductor film is a CAAC-OS film.

The CAAC-OS film is not absolutely amorphous. The CAAC-OS film, for example, includes an oxide semiconductor film with a crystal-amorphous mixed phase structure where crystal parts and amorphous parts are intermingled. Note that in most cases, the crystal part fits inside a cube whose one side is less than 100 nm. In an image obtained with a transmission electron microscope (TEM), a boundary between an amorphous part and a crystal part and a boundary between crystal parts in the CAAC-OS film are not clearly detected. Further, with the TEM, a grain boundary in the CAAC-OS film is not clearly found. Thus, in the CAAC-OS film, a reduction in electron mobility due to the grain boundary is suppressed.

In each of the crystal parts included in the CAAC-OS film, for example, a c-axis is aligned in a direction parallel to a normal vector of a surface where the CAAC-OS film is formed or a normal vector of a surface of the CAAC-OS film. Further, in each of the crystal parts, metal atoms are arranged in a triangular or hexagonal configuration when seen from the direction perpendicular to the a-b plane, and metal atoms are arranged in a layered manner or metal atoms and oxygen atoms are arranged in a layered manner when seen from the direction perpendicular to the c-axis. Note that, among crystal parts, the directions of the a-axis and the b-axis of one crystal part may be different from those of another crystal part. In this specification, a term “perpendicular” includes a range from 80° to 100°, preferably from 85° to 95°. In addition, a term “parallel” includes a range from −10° to 10°, preferably from −5° to 5°.

In the CAAC-OS film, distribution of crystal parts is not necessarily uniform. For example, in the formation process of the CAAC-OS film, in the case where crystal growth occurs from a surface side of the oxide semiconductor film, the proportion of crystal parts in the vicinity of the surface of the oxide semiconductor film is higher than that in the vicinity of the surface where the oxide semiconductor film is formed in some cases. Further, when an impurity is added to the CAAC-OS film, the crystal part in a region to which the impurity is added becomes amorphous in some cases.

Since the c-axes of the crystal parts included in the CAAC-OS film are aligned in the direction parallel to a normal vector of a surface where the CAAC-OS film is formed or a normal vector of a surface of the CAAC-OS film, the directions of the c-axes may be different from each other depending on the shape of the CAAC-OS film (the cross-sectional shape of the surface where the CAAC-OS film is formed or the cross-sectional shape of the surface of the CAAC-OS film). Note that the film deposition is accompanied with the formation of the crystal parts or followed by the formation of the crystal parts through crystallization treatment such as heat treatment. Hence, the c-axes of the crystal parts are aligned in the direction parallel to a normal vector of the surface where the CAAC-OS film is formed or a normal vector of the surface of the CAAC-OS film.

In a transistor using the CAAC-OS film, change in electric characteristics due to irradiation with visible light or ultraviolet light is small. Thus, the transistor has high reliability.

The oxide semiconductor film has a wider band gap than a silicon film by approximately 1 eV to 2 eV. For that reason, in the transistor including the oxide semiconductor film, impact ionization is unlikely to occur and avalanche breakdown is unlikely to occur. That is, it can be said that, in the transistor including the oxide semiconductor film, hot-carrier degradation is unlikely to occur.

Furthermore, in the case where the oxide semiconductor film is used as the semiconductor film 106 as described above, carriers are unlikely to be generated in the oxide semiconductor film; accordingly, the channel region can be completely depleted by an electric field of the gate electrode 104 even when the semiconductor film 106 has a large thickness (for example, greater than or equal to 15 nm and less than 100 nm). For that reason, in the transistor including the oxide semiconductor film, an increase in off-state current and a change in threshold voltage due to a punch-through phenomenon are not caused. When the channel length is, for example, 3 μm, the off-state current can be lower than 10⁻²¹ A or lower than 10⁻²⁴ A per micrometer of channel width at room temperature.

The oxygen vacancies in the oxide semiconductor film, which are a factor of generating carriers, can be evaluated by electron spin resonance (ESR). That is, an oxide semiconductor film with few oxygen vacancies can be referred to as an oxide semiconductor film which does not have a signal due to oxygen vacancies evaluated by ESR. Specifically, the spin density attributed to oxygen vacancies in the oxide semiconductor film is lower than 5×10¹⁶ spins/cm³. When the oxide semiconductor film has oxygen vacancies, a signal having symmetry is found at a g value of around 1.93 in ESR.

There is no particular limitation on the substrate 100 as long as it has heat resistance enough to withstand at least heat treatment performed later. For example, a glass substrate, a ceramic substrate, a quartz substrate, or a sapphire substrate may be used as the substrate 100. Alternatively, a single crystal semiconductor substrate or a polycrystalline semiconductor substrate made of silicon, silicon carbide, or the like, a compound semiconductor substrate made of silicon germanium or the like, a silicon-on-insulator (SOI) substrate, or the like may be used. Still alternatively, any of these substrates provided with a semiconductor element may be used as the substrate 100.

In the case of using a large glass substrate such as the fifth generation (1000 mm×1200 mm or 1300 mm×1500 mm), the sixth generation (1500 mm×1800 mm), the seventh generation (1870 mm×2200 mm), the eighth generation (2200 mm×2500 mm), the ninth generation (2400 mm×2800 mm), or the tenth generation (2880 mm×3130 mm) as the substrate 100, microfabrication is difficult in some cases due to the shrinkage of the substrate 100, which is caused by heat treatment or the like in a manufacturing process of the semiconductor device. Therefore, in the case where the above-described large glass substrate is used as the substrate 100, a substrate which is unlikely to shrink through the heat treatment is preferably used. For example, a large-sized glass substrate which has a shrinkage of 10 ppm or less, preferably 5 ppm or less, more preferably 3 ppm or less after heat treatment at 400° C., preferably at 450° C., more preferably 500° C. for one hour may be used as the substrate 100.

Further alternatively, a flexible substrate may be used as the substrate 100. Note that as a method for forming a transistor over a flexible substrate, there is a method in which, after a transistor is formed over a non-flexible substrate, the transistor is separated from the non-flexible substrate and transferred to the substrate 100 which is a flexible substrate. In that case, a separation layer is preferably provided between the non-flexible substrate and the transistor.

The base insulating film 102 may be formed of a single layer or a stacked layer using an insulating film containing one or more of aluminum oxide, magnesium oxide, silicon oxide, silicon oxynitride, silicon nitride oxide, silicon nitride, germanium oxide, yttrium oxide, zirconium oxide, lanthanum oxide, neodymium oxide, hafnium oxide, and tantalum oxide.

The amount of oxygen is larger than that of nitrogen in silicon oxynitride, and the amount of nitrogen is larger than that of oxygen in silicon nitride oxide.

The base insulating film 102 is preferably an insulating film containing excess oxygen.

In the case where the base insulating film 102 is an insulating film containing excess oxygen, oxygen vacancies in the oxide semiconductor film can be reduced.

An insulating film containing excess oxygen refers to an insulating film in which the amount of released oxygen which is converted into oxygen atoms is greater than or equal to 1×10¹⁸ atoms/cm³, greater than or equal to 1×10¹⁹ atoms/cm³, or greater than or equal to 1×10²⁰ atoms/cm³ in thermal desorption spectroscopy (TDS).

Here, a method for measuring the amount of released oxygen using TDS will be described.

The total amount of released gas in TDS is proportional to the integral value of the ion intensity of the released gas. Then, this integral value is compared with the reference value of a standard sample, whereby the total amount of the released gas can be calculated.

For example, the number of released oxygen molecules (N_{O2}) from an insulating film can be calculated according to Formula (I) using the TDS results of a silicon wafer containing hydrogen at a predetermined density, which is the standard sample, and the TDS results of the insulating film. Here, all gasses having a mass number of 32 which are obtained by the TDS are assumed to originate from an oxygen molecule. CH₃OH can be given as a gas having a mass number of 32, but is not taken into consideration on the assumption that CH₃OH is unlikely to be present. Further, an oxygen molecule including an oxygen atom having a mass number of 17 or 18, which is an isotope of an oxygen atom, is also not taken into consideration because the proportion of such a molecule in the natural world is minimal

$${N}_{O 2} = \frac{{N}_{H 2}}{{S}_{H 2}} \times {S}_{O 2} \times α \qquad ( 1 )$$

N_{H2} is the value obtained by conversion of the number of hydrogen molecules desorbed from the standard sample into density. S_{H2} is the integral value of ion intensity when the standard sample is analyzed by TDS. Here, the reference value of the standard sample is expressed by N_{H2}/S_{H2}. S_{O2} is the integral value of ion intensity when the insulating film is analyzed by TDS, and α is a coefficient affecting the ion intensity in the TDS. For details of Formula (1), Japanese Published Patent Application No. H6-275697 is referred to. Note that the amount of released oxygen from the insulating film was measured with a thermal desorption spectroscopy apparatus produced by ESCO Ltd., EMD-WA1000S/W using a silicon wafer containing hydrogen atoms at 1×10¹⁶ atoms/cm² as the standard sample.

Further, in the TDS, oxygen is partly detected as an oxygen atom. The ratio between oxygen molecules and oxygen atoms can be calculated from the ionization rate of oxygen molecules. Note that, since the above α is determined considering the ionization rate of oxygen molecules, the number of released oxygen atoms can be estimated through the evaluation of the number of the released oxygen molecules.

Note that N_{O2} is the number of released oxygen molecules. When the number of released oxygen molecules is converted into the number of released oxygen atoms, the number of released oxygen atoms is twice the number of released oxygen molecules.

The insulating film containing excess oxygen may contain a peroxide radical. Specifically, the spin density attributed to a peroxide radical of the insulating film is 5×10¹⁷ spins/cm³ or higher. Note that the insulating film containing a peroxide radical has a signal having asymmetry at a g value of around 2.01 in ESR.

The insulating film containing excess oxygen may be formed using oxygen-excess silicon oxide (SiOₓ(X>2)). In the oxygen-excess silicon oxide (Sia, (X>2)), the number of oxygen atoms per unit volume is more than twice the number of silicon atoms per unit volume. The number of silicon atoms and the number of oxygen atoms per unit volume are measured by RBS.

The gate insulating film 112 may be formed of a single layer or a stacked layer using an insulating film containing one or more of aluminum oxide, magnesium oxide, silicon oxide, silicon oxynitride, silicon nitride oxide, silicon nitride, germanium oxide, yttrium oxide, zirconium oxide, lanthanum oxide, neodymium oxide, hafnium oxide, and tantalum oxide.

The gate insulating film 112 is preferably an insulating film containing excess oxygen.

In the case where the gate insulating film 112 is an insulating film containing excess oxygen, oxygen vacancies in the oxide semiconductor film can be reduced.

The gate electrode 104 may be formed of a single layer or a stacked layer using one or more conductive films containing a simple substance selected from Al, Ti, Cr, Co, Ni, Cu, Y, Zr, Mo, Ag, Ta, and W; a nitride containing one or more kinds of the above substances; an oxide containing one or more kinds of the above substances; or an alloy containing one or more kinds of the above substances.

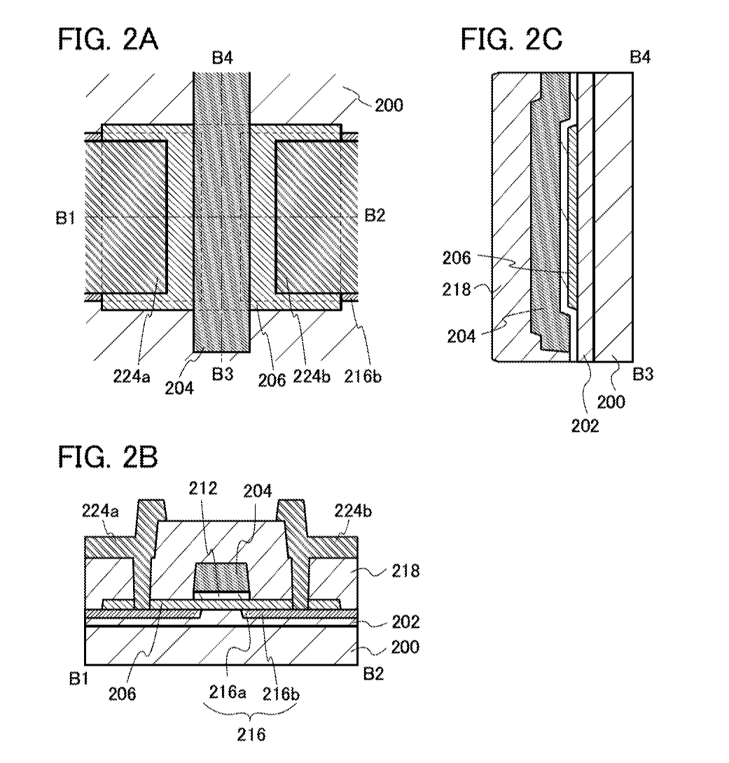

Next, a transistor having a structure different from that in FIGS. 1A to 1C will be described with reference to FIGS. 2A to 2C.

The transistor illustrated in FIGS. 2A to 2C is different from the transistor illustrated in FIGS. 1A to 1C in that a pair of semiconductor layers is embedded in a base insulating film.

FIG. 2A is a top view of a transistor according to one embodiment of the present invention. FIG. 2B is a cross-sectional view taken along dashed-dotted line B1-B2 in FIG. 2A. FIG. 2C is a cross-sectional view taken along dashed-dotted line B3-B4 in FIG. 2A. Note that a gate insulating film 212 and the like are not illustrated in FIG. 2A for easy understanding.

FIG. 2B is a cross-sectional view of the transistor including a base insulating film 202 having depressions, over a substrate 200; a pair of semiconductor layers 216 each including a region 216a and a region 216b and filling the depression of the base insulating film 202; a semiconductor film 206 over the base insulating film 202 and the pair of semiconductor layers 216; the gate insulating film 212 over the semiconductor film 206; and a gate electrode 204 overlapping with the semiconductor film 206, over the gate insulating film 212.

In the cross-sectional view of FIG. 2B, a protective insulating film 218 is provided over the semiconductor film 206 and the gate electrode 204. Note that the protective insulating film 218 has openings reaching the pair of semiconductor layers 216. A wiring 224a and a wiring 224b over the protective insulating film 218 are in contact with the pair of semiconductor layers 216 through the openings.

The gate insulating film 212 is provided only in a region overlapping with the gate electrode 204 in FIG. 2B; however, one embodiment of the present invention is not limited thereto. For example, the gate insulating film 212 may be provided so as to cover the semiconductor film 206.

In the pair of semiconductor layers 216, the regions 216a overlap with the gate electrode 204. The regions 216b do not overlap with the gate electrode 204.

The pair of semiconductor layers 216 contains silicon, germanium, zinc oxide, indium oxide, or tin oxide.

In the pair of semiconductor layers 216, the regions 216b are each a low-resistance region. On the other hand, the regions 216a are each a high-resistance region.

In the pair of semiconductor layers 216, the regions 216b are each a region which contains impurities generating carriers in the pair of semiconductor layers 216. The regions 216a are each a region which does not contain impurities generating carriers in the pair of semiconductor layers 216.

In the case where the pair of semiconductor layers 216 contains a Group 14 element such as silicon or germanium, the regions 216b contain a trivalent element (boron, aluminum, gallium, indium, or the like) or a pentavalent element (phosphorus, arsenic, antimony, or the like).

Further, in the case where the pair of semiconductor layers 216 contains zinc oxide, the regions 216b contain a trivalent element (aluminum, gallium, indium, or the like). In the case where the pair of semiconductor layers 216 contains indium oxide, the regions 216b contain a quadrivalent element (tin, titanium, zirconium, hafnium, cerium, or the like). In the case where the pair of semiconductor layers 216 contains tin oxide, the regions 216b contain fluorine, antimony, or the like.

The gate electrode 204 does not overlap with the regions 216b as described above, whereby the parasitic capacitance of the transistor in FIGS. 2A to 2C is small.

The regions 216b of the pair of semiconductor layers 216 function as a source electrode and a drain electrode of the transistor. The regions 216b functioning as the source electrode and the drain electrode are extended to the vicinity of a channel region (a region overlapping with the gate electrode 204, in the semiconductor film 206), whereby the parasitic resistance of the transistor in FIGS. 2A to 2C can be made lower and the parasitic capacitance thereof can be made smaller.

The semiconductor film 206 may be any of the semiconductor films given as examples of the semiconductor film 106.

In the transistor illustrated in FIGS. 2A to 2C, the pair of semiconductor layers 216 is provided so as to fill the depressions of the base insulating film 202, and is level with the base insulating film 202. For that reason, the semiconductor film 206 can be provided on a flat surface of the base insulating film 202 and the pair of semiconductor layers 216. In a miniaturized transistor, a slight difference in level causes a defect in shape in some cases; thus, the structure of the transistor illustrated in FIGS. 2A to 2C is suitable for miniaturization.

The base insulating film 202 may be any of the insulating films given as examples of the base insulating film 102.

The base insulating film 202 is preferably an insulating film containing excess oxygen.

In the case where the base insulating film 202 is an insulating film containing excess oxygen, oxygen vacancies in the oxide semiconductor film can be reduced.

The gate insulating film 212 may be any of the insulating films given as examples of the gate insulating film 112.

The gate insulating film 212 is preferably an insulating film containing excess oxygen.

In the case where the gate insulating film 212 is an insulating film containing excess oxygen, oxygen vacancies in the oxide semiconductor film can be reduced.

The gate electrode 204 may be any of the conductive films given as examples of the gate electrode 104.

The protective insulating film 218 may be formed of a single layer or a stacked layer using an insulating film containing one or more of aluminum oxide, magnesium oxide, silicon oxide, silicon oxynitride, silicon nitride oxide, silicon nitride, germanium oxide, yttrium oxide, zirconium oxide, lanthanum oxide, neodymium oxide, hafnium oxide, and tantalum oxide.

The protective insulating film 218 is preferably an insulating film containing excess oxygen.

In the case where the protective insulating film 218 is an insulating film containing excess oxygen, oxygen vacancies in the oxide semiconductor film can be reduced.

The wiring 224a and the wiring 224b may be formed of a single layer or a stacked layer using one or more conductive films containing a simple substance selected from Al, Ti, Cr, Co, Ni, Cu, Y, Zr, Mo, Ag, Ta, and W; a nitride containing one or more kinds of the above substances; an oxide containing one or more kinds of the above substances; or an alloy containing one or more kinds of the above substances.

In the case where the pair of semiconductor layers 216 contains silicon, the pair of semiconductor layers 216 in contact with the wirings 224a and 224b may contain silicide. With silicide, the contact resistance between the pair of semiconductor layers 216 and the wirings 224a and 224b can be reduced. Consequently, the parasitic resistance of the transistor can be reduced, and the on-state current of the transistor can be increased.

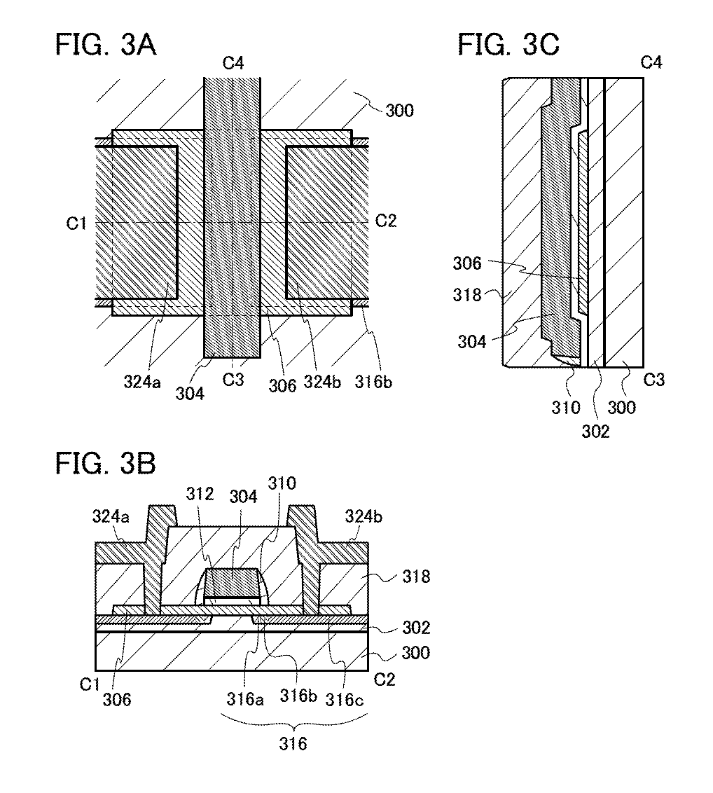

Next, a transistor having a structure different from those in FIGS. 1A to 1C and FIGS. 2A to 2C will be described with reference to FIGS. 3A to 3C.

The transistor illustrated in FIGS. 3A to 3C is different from the transistor illustrated in FIGS. 2A to 2C in that sidewall insulating films 310 are provided in contact with side surfaces of the gate electrode 304, and each of a pair of semiconductor layers 316 includes a region overlapping with the gate electrode 304, a region overlapping with the sidewall insulating film 310, and a region overlapping with neither the sidewall insulating film 310 nor the gate electrode 304.

Although not illustrated, the transistor illustrated in FIGS. 1A to 1C may have a structure in which sidewall insulating films are provided in contact with side surfaces of the gate electrode 104, like the transistor illustrated in FIGS. 3A to 3C. In that case, each of the pair of semiconductor layers 116 may include a region overlapping with the gate electrode 104, a region overlapping with the sidewall insulating film, and a region overlapping with neither the sidewall insulating film nor the gate electrode 104.

FIG. 3A is a top view of a transistor according to one embodiment of the present invention. FIG. 3B is a cross-sectional view taken along dashed-dotted line C1-C2 in FIG. 3A. FIG. 3C is a cross-sectional view taken along dashed-dotted line C3-C4 in FIG. 3A. Note that a gate insulating film 312 and the like are not illustrated in FIG. 3A for easy understanding.

FIG. 3B is a cross-sectional view of the transistor including a base insulating film 302 having depressions, over a substrate 300; the pair of semiconductor layers 316 each including a region 316a, a region 316b, and a region 316c and filling the depression of the base insulating film 302; a semiconductor film 306 over the base insulating film 302 and the pair of semiconductor layers 316; the gate insulating film 312 over the semiconductor film 306; the gate electrode 304 overlapping with the semiconductor film 306, over the gate insulating film 312; and the sidewall insulating films 310 in contact with the side surfaces of the gate electrode 304.

In the cross-sectional view of FIG. 3B, a protective insulating film 318 is provided over the semiconductor film 306, the gate electrode 304, and the sidewall insulating films 310. Note that the protective insulating film 318 has openings reaching the pair of semiconductor layers 316. A wiring 324a and a wiring 324b over the protective insulating film 318 are in contact with the pair of semiconductor layers 316 through the openings.

The gate insulating film 312 is provided only in a region overlapping with the gate electrode 304 in FIG. 3B; however, one embodiment of the present invention is not limited thereto. For example, the gate insulating film 312 may be provided so as to cover the semiconductor film 306. Alternatively, the gate insulating film 312 may be provided only in a region overlapping with the gate electrode 304 and the sidewall insulating films 310.

In the pair of semiconductor layers 316, the regions 316a overlap with the gate electrode 304. The regions 316b overlap with the sidewall insulating films 310. The regions 316c overlap with neither the gate electrode 304 nor the sidewall insulating films 310.

The pair of semiconductor layers 316 contains silicon, germanium, zinc oxide, indium oxide, or tin oxide.

In the pair of semiconductor layers 316, the regions 316b and the regions 316c are each a low-resistance region. Note that the resistivity of the regions 316b is higher than that of the regions 316c. Specifically, the regions 316b have a resistivity higher than or equal to 1 mΩcm and lower than or equal to 100 Ωcm, or higher than or equal to 10 mΩcm and lower than or equal to 100 Ωcm. Further, the regions 316c have a resistivity higher than or equal to 1 μΩcm and lower than or equal to 1 Ωcm, or higher than or equal to 1 μΩcm and lower than or equal to 100 mΩcm. Note that the regions 316a are each a high-resistance region. Note that the resistivity of the regions 316a is higher than that of the regions 316c. Like the regions 316a, the regions 316b each may be a high-resistance region.

In the pair of semiconductor layers 316, the regions 316b and the regions 316c are each a region containing impurities generating carriers in the pair of semiconductor layers 316. Note that the regions 316b have a lower concentration of impurities generating carriers than the regions 316c. Specifically, the regions 316b have a concentration of impurities generating carriers higher than or equal to 1×10¹⁴ atoms/cm³ and lower than or equal to 1×10²¹ atoms/cm³, or higher than or equal to 1×10¹⁴ atoms/cm³ and lower than or equal to 1×10²⁰ atoms/cm³. Further, the regions 316c have a concentration of impurities generating carriers higher than or equal to 1×10¹⁶ atoms/cm³ and lower than or equal to 1×10²² atoms/cm³, or higher than or equal to 1×10¹⁸ atoms/cm³ and lower than or equal to 1×10²² atoms/cm³. Furthermore, the regions 316a are each a region which does not contain impurities generating carriers in the pair of semiconductor layers 316. Like the regions 316a, the regions 316b each may be a region which does not contain impurities generating carriers in the pair of semiconductor layers 316.

In the case where the pair of semiconductor layers 316 contains a Group 14 element such as silicon or germanium, the regions 316b and the regions 316c contain a trivalent element (boron, aluminum, gallium, indium, or the like) or a pentavalent element (phosphorus, arsenic, antimony, or the like).

Further, in the case where the pair of semiconductor layers 316 contains zinc oxide, the regions 316b and the regions 316c contain a trivalent element (aluminum, gallium, indium, or the like). In the case where the pair of semiconductor layers 316 contains indium oxide, the regions 316b and the regions 316c contain a quadrivalent element (tin, titanium, zirconium, hafnium, cerium, or the like). In the case where the pair of semiconductor layers 316 contains tin oxide, the regions 316b and the regions 316c contain fluorine, antimony, or the like.

The gate electrode 304 does not overlap with the regions 316c as described above, whereby the parasitic capacitance of the transistor in FIGS. 3A to 3C is small.

Here, the regions 316b of the pair of semiconductor layers 316 function as LDD regions or offset regions of the transistor. The regions 316c function as a source electrode and a drain electrode of the transistor. The regions 316c functioning as the source electrode and the drain electrode are extended to the vicinity of a channel region (a region overlapping with the gate electrode 304, in the semiconductor film 306), whereby the parasitic resistance of the transistor in FIGS. 3A to 3C can be made lower and the parasitic capacitance thereof can be made smaller. The regions 316b functioning as the LDD regions or the offset regions are each provided between the channel formation region and the region 316c functioning as the source electrode or the drain electrode; thus, hot-carrier degradation and drain induced barrier lowering (DIBL) can be suppressed.

The semiconductor film 306 may be any of the semiconductor films given as examples of the semiconductor film 106.

In the transistor illustrated in FIGS. 3A to 3C, the pair of semiconductor layers 316 is provided so as to fill the depressions of the base insulating film 302, and is level with the base insulating film 302. For that reason, the semiconductor film 306 can be provided on a flat surface of the base insulating film 302 and the pair of semiconductor layers 316. In a miniaturized transistor, a slight difference in level causes a defect in shape in some cases; thus, the structure of the transistor illustrated in FIGS. 3A to 3C is suitable for miniaturization. Like the transistor illustrated in FIGS. 1A to 1C, the transistor illustrated in FIGS. 3A to 3C may have a structure in which the semiconductor film extends beyond a step formed by the pair of semiconductor layers.

The base insulating film 302 may be any of the insulating films given as examples of the base insulating film 102.

The base insulating film 302 is preferably an insulating film containing excess oxygen.

In the case where the base insulating film 302 is an insulating film containing excess oxygen, oxygen vacancies in the oxide semiconductor film can be reduced.

The gate insulating film 312 may be any of the insulating films given as examples of the gate insulating film 112.

The gate insulating film 312 is preferably an insulating film containing excess oxygen.

In the case where the gate insulating film 312 is an insulating film containing excess oxygen, oxygen vacancies in the oxide semiconductor film can be reduced.

The gate electrode 304 may be any of the conductive films given as examples of the gate electrode 104.

The protective insulating film 318 may be any of the insulating films given as examples of the protective insulating film 218.

The protective insulating film 318 is preferably an insulating film containing excess oxygen.

In the case where the protective insulating film 318 is an insulating film containing excess oxygen, oxygen vacancies in the oxide semiconductor film can be reduced.

The wiring 324a and the wiring 324b may be any of the conductive films given as examples of the wiring 224a and the wiring 224b.

In the case where the pair of semiconductor layers 316 contains silicon, the pair of semiconductor layers 316 in contact with the wirings 324a and 324b may contain silicide. With silicide, the contact resistance between the pair of semiconductor layers 316 and the wirings 324a and 324b can be reduced. Consequently, the parasitic resistance of the transistor can be reduced, and the on-state current of the transistor can be increased. Alternatively, in the case where the pair of semiconductor layers 316 does not contain silicon, the pair of semiconductor layers 316 in contact with the wirings 324a and 324b may include a mixed layer or an alloy layer.

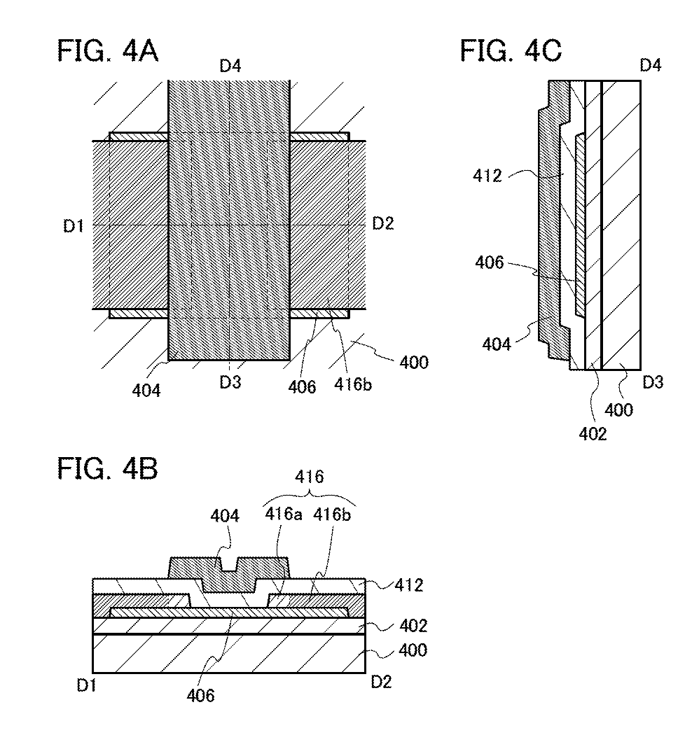

Next, a transistor having a structure different from those in FIGS. 1A to 1C, FIGS. 2A to 2C, and FIGS. 3A to 3C will be described with reference to FIGS. 4A to 4C.

The transistor illustrated in FIGS. 4A to 4C is different from the transistor illustrated in FIGS. 1A to 1C in that a pair of semiconductor layers is provided in contact with a top surface of a semiconductor film.

Although not illustrated, like the transistor illustrated in FIGS. 3A to 3C, the transistor illustrated in FIGS. 4A to 4C may have a structure in which sidewall insulating films are provided in contact with side surfaces of a gate electrode 404 and a pair of semiconductor layers 416 each includes a region overlapping with the gate electrode 404, a region overlapping with the sidewall insulating film, and a region overlapping with neither the sidewall insulating film nor the gate electrode 404.

FIG. 4A is a top view of a transistor according to one embodiment of the present invention. FIG. 4B is a cross-sectional view taken along dashed-dotted line D1-D2 in FIG. 4A. FIG. 4C is a cross-sectional view taken along dashed-dotted line D3-D4 in FIG. 4A. Note that a gate insulating film 412 and the like are not illustrated in FIG. 4A for easy understanding.

FIG. 4B is a cross-sectional view of the transistor including a base insulating film 402 over a substrate 400; a semiconductor film 406 over the base insulating film 402; the pair of semiconductor layers 416 each including a region 416a and a region 416b, over the semiconductor film 406; the gate insulating film 412 over the semiconductor film 406 and the pair of semiconductor layers 416; and the gate electrode 404 overlapping with the semiconductor film 406, over the gate insulating film 412.

In the pair of semiconductor layers 416, the regions 416a overlap with the gate electrode 404. The regions 416b do not overlap with the gate electrode 404.

The pair of semiconductor layers 416 contains silicon, germanium, zinc oxide, indium oxide, or tin oxide.

In the pair of semiconductor layers 416, the regions 416b are each a low-resistance region. On the other hand, the regions 416a are each a high-resistance region.

In the pair of semiconductor layers 416, the regions 416b are each a region which contains impurities generating carriers in the pair of semiconductor layers 416. The regions 416a are each a region which does not contain impurities generating carriers in the pair of semiconductor layers 416.

In the case where the pair of semiconductor layers 416 contains a Group 14 element such as silicon or germanium, the regions 416b contain a trivalent element (boron, aluminum, gallium, indium, or the like) or a pentavalent element (phosphorus, arsenic, antimony, or the like).

Further, in the case where the pair of semiconductor layers 416 contains zinc oxide, the regions 416b contain a trivalent element (aluminum, gallium, indium, or the like). In the case where the pair of semiconductor layers 416 contains indium oxide, the regions 416b contain a quadrivalent element (tin, titanium, zirconium, hafnium, cerium, or the like). In the case where the pair of semiconductor layers 416 contains tin oxide, the regions 416b contain fluorine, antimony, or the like.

The gate electrode 404 does not overlap with the regions 416b as described above, whereby the parasitic capacitance of the transistor in FIGS. 4A to 4C is small.

The regions 416b of the pair of semiconductor layers 416 function as a source electrode and a drain electrode of the transistor. The regions 416b functioning as the source electrode and the drain electrode are extended to the vicinity of a channel region (a region overlapping with the gate electrode 404, in the semiconductor film 406), whereby the parasitic resistance of the transistor in FIGS. 4A to 4C can be made lower and the parasitic capacitance thereof can be made smaller.

The semiconductor film 406 may be any of the semiconductor films given as examples of the semiconductor film 106.

The base insulating film 402 may be any of the insulating films given as examples of the base insulating film 102.

The base insulating film 402 is preferably an insulating film containing excess oxygen.

In the case where the base insulating film 402 is an insulating film containing excess oxygen, oxygen vacancies in the oxide semiconductor film can be reduced.

The gate insulating film 412 may be any of the insulating films given as examples of the gate insulating film 112.

The gate insulating film 412 is preferably an insulating film containing excess oxygen.

In the case where the gate insulating film 412 is an insulating film containing excess oxygen, oxygen vacancies in the oxide semiconductor film can be reduced.

The gate electrode 404 may be any of the conductive films given as examples of the gate electrode 104.

The structures of the transistors described above can be combined with each other as appropriate.

The parasitic resistance of each of the transistors described in this embodiment is low and the parasitic capacitance thereof is small.

This embodiment shows an example of a basic principle. Thus, part or the whole of this embodiment can be freely combined with, applied to, or replaced with part or the whole of another embodiment.

### Embodiment 2

In this embodiment, methods for manufacturing the transistors described in Embodiment 1 will be described.

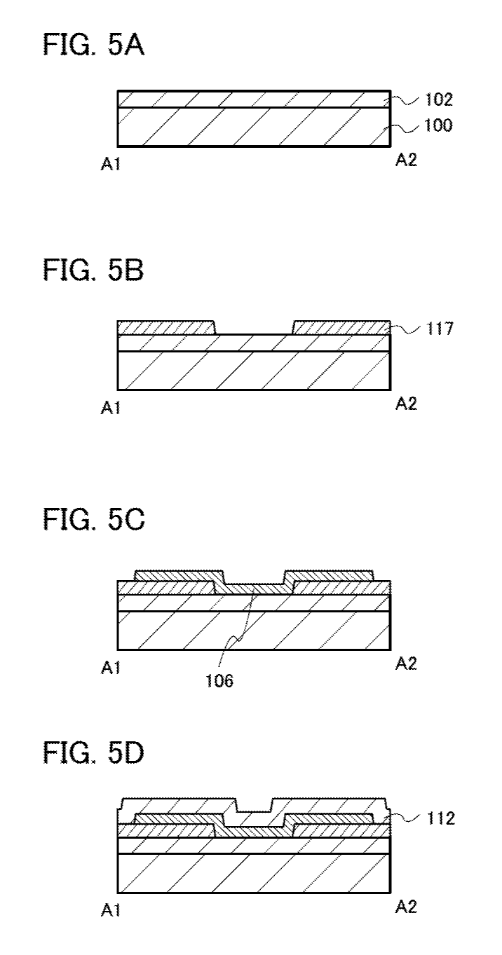

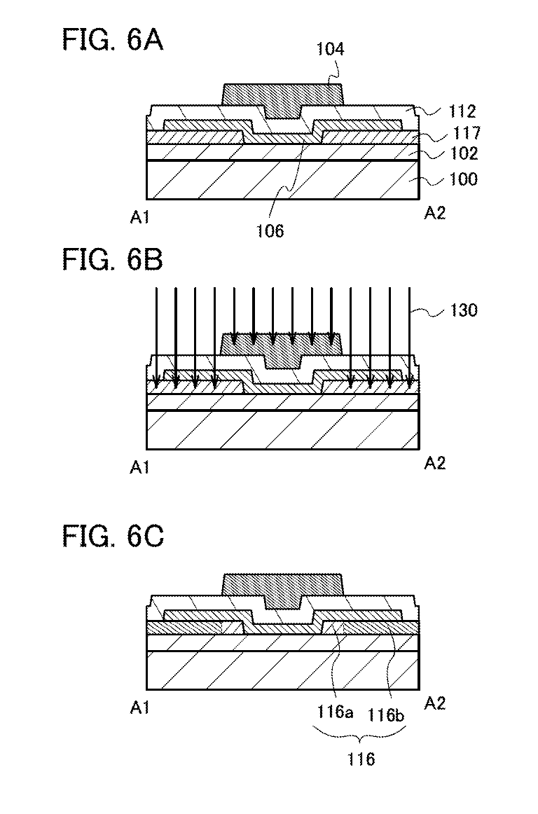

First, a method for manufacturing the transistor illustrated in FIGS. 1A to 1C will be described with reference to FIGS. 5A to 5D and FIGS. 6A to 6C. Note that for easy understanding, FIGS. 5A to 5D and FIGS. 6A to 6C only illustrate cross-sectional views of the transistor corresponding to FIG. 1B.

First, the substrate 100 is prepared. As the substrate 100, any of the substrates given as examples of the substrate 100 can be used.

Next, the base insulating film 102 is formed (see FIG. 5A). The base insulating film 102 may be any of the insulating films given as examples of the base insulating film 102, and formed by a sputtering method, a chemical vapor deposition (CVD) method, a molecular beam epitaxy (MBE) method, an atomic layer deposition (ALD) method, or a pulsed laser deposition (PLD) method.

The use of a microwave CVD method as a CVD method can reduce plasma damage to a deposition surface. Further, a dense film with few defects can be formed even at relatively low temperature (about 325° C.) because high-density plasma is used. Note that a microwave CVD method is also called a high-density plasma CVD method. In this specification, a simple term “CVD method” includes a microwave CVD method and the like.

For example, a silicon oxide film is preferably formed as the base insulating film 102 by an RF sputtering method using a quartz (preferably synthetic quartz) target under the following conditions: the substrate heating temperature is higher than or equal to 30° C. and lower than or equal to 450° C. (preferably higher than or equal to 70° C. and lower than or equal to 200° C.); the distance between the substrate and the target (the T-S distance) is longer than or equal to 20 mm and shorter than or equal to 400 mm (preferably longer than or equal to 40 mm and shorter than or equal to 200 mm); the pressure is higher than or equal to 0.1 Pa and lower than or equal to 4 Pa (preferably higher than or equal to 0.2 Pa and lower than or equal to 1.2 Pa); the high-frequency power source is higher than or equal to 0.5 kW and lower than or equal to 12 kW (preferably higher than or equal to 1 kW and lower than or equal to 5 kW); and the proportion of O₂/(O₂+Ar) in the deposition gas is higher than or equal to 20% and lower than or equal to 100% (preferably higher than or equal to 50% and lower than or equal to 100%). Note that a silicon target may be used as the target instead of the quartz (preferably synthetic quartz) target. Note that an oxygen gas or a mixed gas of oxygen and argon is used as the deposition gas. With the use of such a method, the base insulating film 102 can be an insulating film containing excess oxygen.

Next, a semiconductor film to be the pair of semiconductor layers 116 is formed. The semiconductor film to be the pair of semiconductor layers 116 may be any of the semiconductor layers given as examples of the pair of semiconductor layers 116, and formed by a sputtering method, a CVD method, an MBE method, an ALD method, or a PLD method.

Next, the semiconductor film to be the pair of semiconductor layers 116 is processed to form a pair of semiconductor layers 117 (see FIG. 5B).

Then, a semiconductor film to be the semiconductor film 106 is formed. The semiconductor film to be the semiconductor film 106 may be any of the semiconductor films given as examples of the semiconductor film 106, and formed by a sputtering method, a CVD method, an MBE method, an ALD method, or a PLD method. The semiconductor film to be the semiconductor film 106 is preferably an oxide semiconductor film formed by a sputtering method. The reason why a sputtering method is preferable is that an oxide semiconductor film having high density and crystallinity can be easily formed. Further, the oxide semiconductor film is preferably formed while the substrate is heated at a temperature higher than or equal to 100° C. and lower than or equal to 450° C. because an oxide semiconductor film having high density and crystallinity can be easily formed.

After the oxide semiconductor film is formed, first heat treatment may be performed. The first heat treatment may be performed at a temperature higher than or equal to 250° C. and lower than or equal to 650° C., preferably higher than or equal to 300° C. and lower than or equal to 500° C. The first heat treatment is performed in an inert gas atmosphere, an atmosphere containing an oxidizing gas at 10 ppm or more, 1% or more, or 10% or more, or under reduced pressure. Alternatively, the first heat treatment may be performed in such a manner that heat treatment is performed in an inert gas atmosphere, and then another heat treatment is performed in an atmosphere containing an oxidizing gas at 10 ppm or more, 1% or more, or 10% or more in order to compensate desorbed oxygen. By the first heat treatment, the crystallinity of the oxide semiconductor film can be improved, and in addition, impurities such as hydrogen and water can be removed from the oxide semiconductor film.

Next, the semiconductor film to be the semiconductor film 106 is processed into the island-shaped semiconductor film 106 (see FIG. 5C).

Note that in the case where the semiconductor film 106 is an oxide semiconductor film, second heat treatment may be performed after the semiconductor film 106 is formed. The second heat treatment may be performed under the conditions described for the first heat treatment. Since the second heat treatment is performed with side surfaces of the oxide semiconductor exposed, impurities such as hydrogen and water are easily removed from the side surfaces of the oxide semiconductor film; thus, impurities can be effectively removed. Note that in the case where the oxide semiconductor film is a CAAC-OS film, impurities are easily diffused along a layer of crystals; thus, impurities such as hydrogen and water are more easily removed from the side surfaces of the oxide semiconductor film.

Next, the gate insulating film 112 is formed (see FIG. 5D). The gate insulating film 112 may be any of the insulating films given as examples of the gate insulating film 112, and formed by a sputtering method, a CVD method, an MBE method, an ALD method, or a PLD method.

Then, a conductive film to be the gate electrode 104 is formed. The conductive film to be the gate electrode 104 may be any of the conductive films given as examples of the gate electrode 104, and formed by a sputtering method, a CVD method, an MBE method, an ALD method, or a PLD method.

After that, the conductive film to be the gate electrode 104 is processed, whereby the gate electrode 104 is formed (see FIG. 6A).

Next, impurities 130 generating carriers in the pair of semiconductor layers 117 are added to the pair of semiconductor layers 117 with the gate electrode 104 used as a mask (see FIG. 6B). As the impurities 130, any of the impurities described in the above embodiment may be used as appropriate. The impurities 130 may be added by an ion implantation method or an ion doping method. Preferably, an ion implantation method is used. At this time, the acceleration voltage is made higher than or equal to 5 kV and lower than or equal to 100 kV. The addition of the impurities 130 is performed such that the concentration of the impurities 130 in the pair of semiconductor layers 117 becomes higher than or equal to 1×10¹⁴ atoms/cm³ and lower than or equal to 1×10²² atoms/cm³, or higher than or equal to 1×10¹⁶ atoms/cm³ and lower than or equal to 1×10²¹ atoms/cm³.

Next, third heat treatment is performed. The third heat treatment may be performed under conditions selected from conditions similar to those of the first heat treatment. Through the third heat treatment, carriers are generated in regions to which the impurities 130 are added in the pair of semiconductor layers 117; thus, the regions 116b are formed. Note that regions to which the impurities 130 are not added in the pair of semiconductor layers 117 become the regions 116a (see FIG. 6C). In the case where the semiconductor film 106 is an oxide semiconductor film and the base insulating film 102 is an insulating film containing excess oxygen, defects in the semiconductor film 106 (oxygen vacancies in the oxide semiconductor film) can be reduced through the third heat treatment.

In the aforementioned manner, the transistor illustrated in FIG. 1A to 1C can be manufactured.

According to the method for manufacturing the transistor in FIGS. 1A to 1C described with reference to FIGS. 5A to 5D and FIGS. 6A to 6C, the pair of semiconductor layers 116 each including the region 116a and the region 116b can be formed in such a manner that the impurities 130 are added to the pair of semiconductor layers 117 with the gate electrode 104 used as a mask. The regions 116b are low-resistance regions, and function as a source electrode and a drain electrode of the transistor. The regions 116b are formed in a self-aligned manner; thus, the parasitic capacitance and parasitic resistance of the transistor can be reduced.

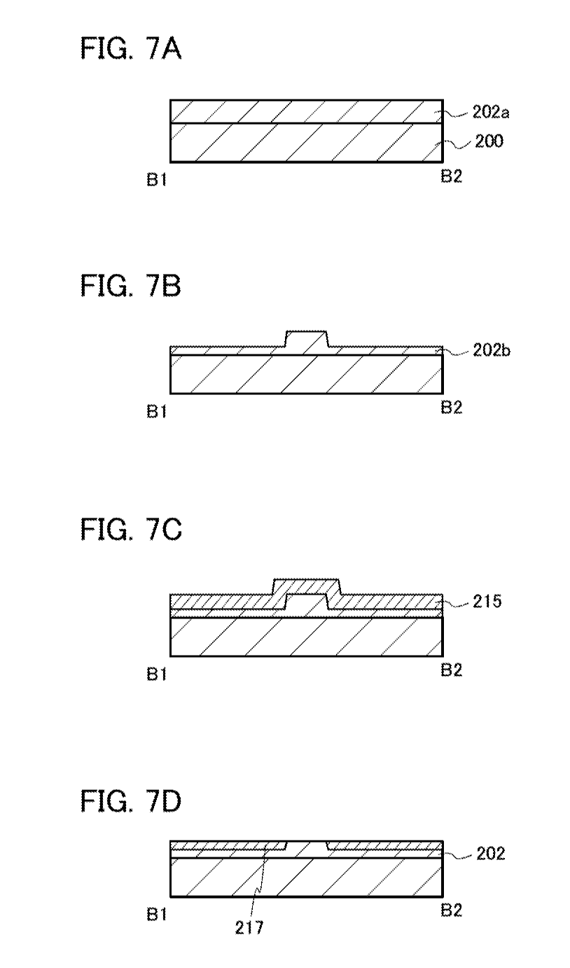

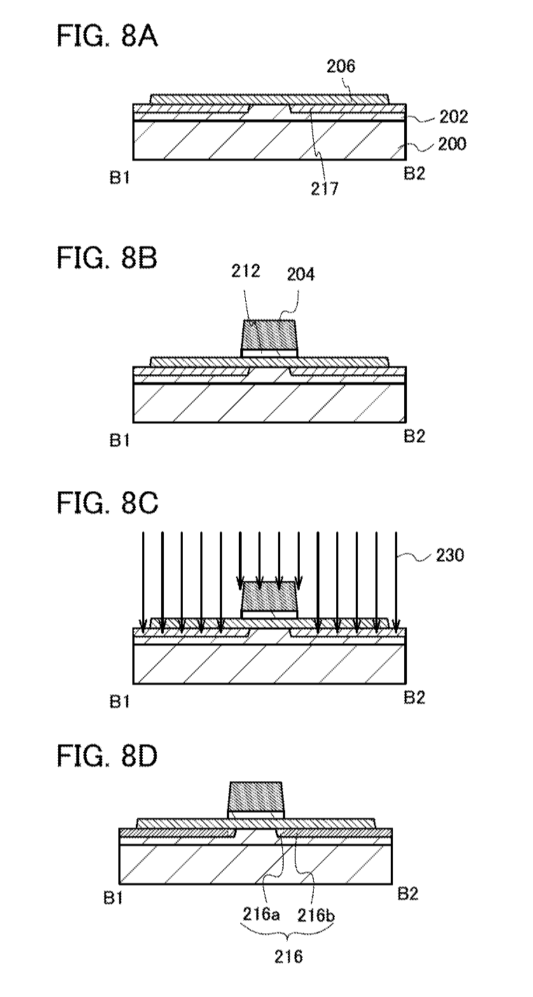

Next, a method for manufacturing the transistor illustrated in FIGS. 2A to 2C will be described with reference to FIGS. 7A to 7D and FIGS. 8A to 8D. Note that for easy understanding, FIGS. 7A to 7D and FIGS. 8A to 8D only illustrate cross-sectional views of the transistor corresponding to FIG. 2B.

First, the substrate 200 is prepared. As the substrate 200, any of the substrates given as examples of the substrate 200 can be used.

Next, an insulating film 202a to be the base insulating film 202 is formed (see FIG. 7A). The insulating film 202a may be any of the insulating films given as examples of the base insulating film 202, and formed by a sputtering method, a CVD method, an MBE method, an ALD method, or a PLD method.

For example, a silicon oxide film is preferably formed as the insulating film 202a to be the base insulating film 202 by an RF sputtering method using a quartz (preferably synthetic quartz) target under the following conditions: the substrate heating temperature is higher than or equal to 30° C. and lower than or equal to 450° C. (preferably higher than or equal to 70° C. and lower than or equal to 200° C.); the distance between the substrate and the target (the T-S distance) is longer than or equal to 20 mm and shorter than or equal to 400 mm (preferably longer than or equal to 40 mm and shorter than or equal to 200 mm); the pressure is higher than or equal to 0.1 Pa and lower than or equal to 4 Pa (preferably higher than or equal to 0.2 Pa and lower than or equal to 1.2 Pa); the high-frequency power source is higher than or equal to 0.5 kW and lower than or equal to 12 kW (preferably higher than or equal to 1 kW and lower than or equal to 5 kW); and the proportion of O₂/(O₂+Ar) in the deposition gas is higher than or equal to 20% and lower than or equal to 100% (preferably higher than or equal to 50% and lower than or equal to 100%). Note that a silicon target may be used as the target instead of the quartz (preferably synthetic quartz) target. Note that an oxygen gas or a mixed gas of oxygen and argon is used as the deposition gas. With the use of such a method, the insulating film 202a to be the base insulating film 202 can be an insulating film containing excess oxygen.

Then, the insulating film 202a is processed to form an insulating film 202b having depressions (see FIG. 7B).

Next, a semiconductor film to be the pair of semiconductor layers 216 is formed. The semiconductor film to be the pair of semiconductor layers 216 may be any of the semiconductor layers given as examples of the pair of semiconductor layers 216, and formed by a sputtering method, a CVD method, an MBE method, an ALD method, or a PLD method.

Next, the semiconductor film to be the pair of semiconductor layers 216 is processed to form an island-shaped semiconductor film 215 (see FIG. 7C).

Then, the insulating film 202b and the semiconductor film 215 are processed such that they are level with each other. This processing may be performed by dry etching treatment or chemical mechanical polishing (CMP) treatment. Through this processing, the insulating film 202b becomes the base insulating film 202 having depressions, and the semiconductor film 215 becomes the pair of semiconductor layers 217 (see FIG. 7D).

Note that in this embodiment, the semiconductor film to be the pair of semiconductor layers 216 is processed into the island-shaped semiconductor film 215, and then the insulating film 202b and the semiconductor film 215 are processed such that they are level with each other; however, one embodiment of the present invention is not limited thereto. For example, the insulating film 202b and the semiconductor film to be the pair of semiconductor layers 216 may be processed such that they are level with each other, and then the semiconductor film to be the pair of semiconductor layers 216 may be processed into island shapes in order to form the pair of semiconductor layers 217.

Here, since the base insulating film 202 and the pair of semiconductor layers 217 are level with each other, a defect in shape of the layers formed through the subsequent steps can be prevented from being caused. Therefore, the transistor can have sable electric characteristics.

Then, a semiconductor film to be the semiconductor film 206 is formed. The semiconductor film to be the semiconductor film 206 may be any of the semiconductor films given as examples of the semiconductor film 206, and formed by a sputtering method, a CVD method, an MBE method, an ALD method, or a PLD method. The semiconductor film to be the semiconductor film 206 is preferably an oxide semiconductor film formed by a sputtering method. The reason why a sputtering method is preferable is that an oxide semiconductor film having high density and crystallinity can be easily formed. Further, the oxide semiconductor film is preferably formed while the substrate is heated at a temperature higher than or equal to 100° C. and lower than or equal to 450° C. because an oxide semiconductor film having high density and crystallinity can be easily formed.

After the oxide semiconductor film is formed, fourth heat treatment may be performed. The fourth heat treatment may be performed under the conditions described for the first heat treatment. By the fourth heat treatment, the crystallinity of the oxide semiconductor film can be improved, and in addition, impurities such as hydrogen and water can be removed from the oxide semiconductor film.

Next, the semiconductor film to be the semiconductor film 206 is processed into the island-shaped semiconductor film 206 (see FIG. 8A).

Next, an insulating film to be the gate insulating film 212 is formed. The insulating film to be the gate insulating film 212 may be any of the insulating films given as examples of the gate insulating film 212, and formed by a sputtering method, a CVD method, an MBE method, an ALD method, or a PLD method.

Next, a conductive film to be the gate electrode 204 is formed. The conductive film to be the gate electrode 204 may be any of the conductive films given as examples of the gate electrode 204, and formed by a sputtering method, a CVD method, an MBE method, an ALD method, or a PLD method.

Then, the conductive film to be the gate electrode 204 is processed to form the gate electrode 204.

Next, the insulating film to be the gate insulating film 212 is processed with the use of the resist mask used for the processing of the gate electrode 204 or with the use of the gate electrode 204 as a mask, whereby the gate insulating film 212 is formed (see FIG. 8B).

Next, impurities 230 generating carriers in the pair of semiconductor layers 217 are added to the pair of semiconductor layers 217 with the gate electrode 204 used as a mask (see FIG. 8C). As the impurities 230, any of the impurities described in the above embodiment may be used as appropriate. The impurities 230 may be added by an ion implantation method or an ion doping method. Preferably, an ion implantation method is used. At this time, the acceleration voltage is made higher than or equal to 5 kV and lower than or equal to 100 kV. The addition of the impurities 230 is performed such that the concentration of the impurities 230 in the pair of semiconductor layers 217 becomes higher than or equal to 1×10¹⁴ atoms/cm³ and lower than or equal to 1×10²² atoms/cm³, or higher than or equal to 1×10¹⁶ atoms/cm³ and lower than or equal to 1×10²¹ atoms/cm³.

Next, fifth heat treatment is performed. The fifth heat treatment may be performed under conditions selected from conditions similar to those of the first heat treatment. Through the fifth heat treatment, carriers are generated in regions to which the impurities 230 are added in the pair of semiconductor layers 217; thus, the regions 216b are formed. Note that regions to which the impurities 230 are not added in the pair of semiconductor layers 217 become the regions 216a. In such a manner, the pair of semiconductor layers 216 is formed (see FIG. 8D). In the case where the semiconductor film 206 is an oxide semiconductor film and the base insulating film 202 is an insulating film containing excess oxygen, defects in the semiconductor film 206 (oxygen vacancies in the oxide semiconductor film) can be reduced through the fifth heat treatment.

In the aforementioned manner, the transistor illustrated in FIG. 2A to 2C can be manufactured.

According to the method for manufacturing the transistor in FIGS. 2A to 2C described with reference to FIGS. 7A to 7D and FIGS. 8A to 8D, the pair of semiconductor layers 216 each including the region 216a and the region 216b can be formed in such a manner that the impurities 230 are added to the pair of semiconductor layers 217 with the gate electrode 204 used as a mask. The regions 216b are low-resistance regions, and function as a source electrode and a drain electrode of the transistor. The regions 216b are formed in a self-aligned manner; thus, the parasitic capacitance and parasitic resistance of the transistor can be reduced.

Next, the protective insulating film 218 is formed. The protective insulating film 218 may be any of the insulating films given as examples of the protective insulating film 218, and formed by a sputtering method, a CVD method, an MBE method, an ALD method, or a PLD method.

Then, the protective insulating film 218 is processed to form openings through which the pair of semiconductor layers 216 is exposed.

Next, a conductive film to be the wiring 224a and the wiring 224b is formed. The conductive film to be the wiring 224a and the wiring 224b may be any of the conductive films given as examples of the wiring 224a and the wiring 224b, and formed by a sputtering method, a CVD method, an MBE method, an ALD method, or a PLD method.

The conductive film to be the wiring 224a and the wiring 224b is processed, whereby the wiring 224a and the wiring 224b are formed.

In the case where the pair of semiconductor layers 216 contains silicon, sixth heat treatment may be performed after the conductive film to be the wirings 224a and 224b is formed so that silicide is formed in portions where the pair of semiconductor layers 216 is in contact with the conductive film to be the wirings 224a and 224b. With silicide, the contact resistance between the pair of semiconductor layers 216 and the wirings 224a and 224b can be reduced. Consequently, the parasitic resistance of the transistor can be reduced, and the on-state current of the transistor can be increased. The sixth heat treatment may be performed under conditions selected from conditions similar to those of the first heat treatment.

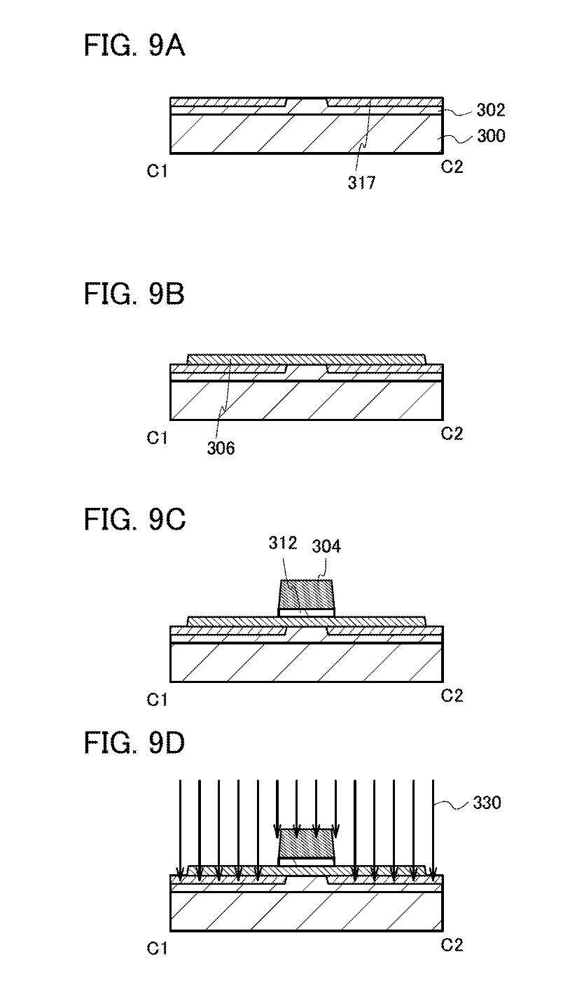

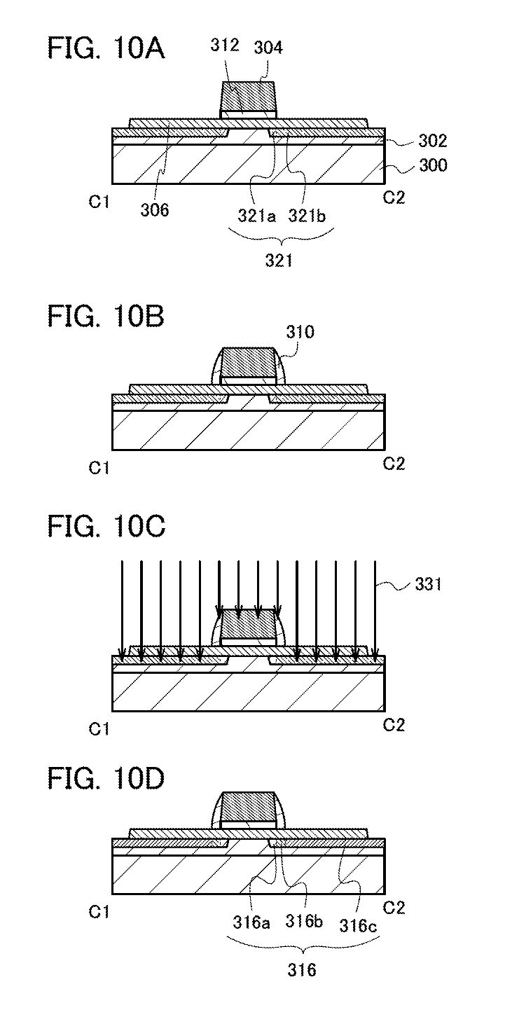

Next, a method for manufacturing the transistor illustrated in FIGS. 3A to 3C will be described with reference to FIGS. 9A to 9D and FIGS. 10A to 10D. Note that for easy understanding, FIGS. 9A to 9D and FIGS. 10A to 10D only illustrate cross-sectional views of the transistor corresponding to FIG. 3B.

First, the substrate 300 is prepared. As the substrate 300, any of the substrates given as examples of the substrate 300 can be used.

Next, an insulating film to be the base insulating film 302 is formed. The insulating film may be any of the insulating films given as examples of the base insulating film 302, and formed by a sputtering method, a CVD method, an MBE method, an ALD method, or a PLD method.

For example, a silicon oxide film is preferably formed as the insulating film to be the base insulating film 302 by an RF sputtering method using a quartz (preferably synthetic quartz) target under the following conditions: the substrate heating temperature is higher than or equal to 30° C. and lower than or equal to 450° C. (preferably higher than or equal to 70° C. and lower than or equal to 300° C.); the distance between the substrate and the target (the T-S distance) is longer than or equal to 20 mm and shorter than or equal to 400 mm (preferably longer than or equal to 40 mm and shorter than or equal to 300 mm); the pressure is higher than or equal to 0.1 Pa and lower than or equal to 4 Pa (preferably higher than or equal to 0.2 Pa and lower than or equal to 1.2 Pa); the high-frequency power source is higher than or equal to 0.5 kW and lower than or equal to 12 kW (preferably higher than or equal to 1 kW and lower than or equal to 5 kW); and the proportion of O₂/(O₂+Ar) in the deposition gas is higher than or equal to 20% and lower than or equal to 100% (preferably higher than or equal to 50% and lower than or equal to 100%). Note that a silicon target may be used as the target instead of the quartz (preferably synthetic quartz) target. Note that an oxygen gas or a mixed gas of oxygen and argon is used as the deposition gas. With the use of such a method, the insulating film to be the base insulating film 302 can be an insulating film containing excess oxygen.

Then, the insulating film to be the base insulating film 302 is processed to form an insulating film having depressions.

Next, a semiconductor film to be the pair of semiconductor layers 316 is formed. The semiconductor film to be the pair of semiconductor layers 316 may be any of the semiconductor layers given as examples of the pair of semiconductor layers 316, and formed by a sputtering method, a CVD method, an MBE method, an ALD method, or a PLD method.

Next, the semiconductor film to be the pair of semiconductor layers 316 is processed to form an island-shaped semiconductor film.

Then, the insulating film having the depressions and the island-shaped semiconductor film are processed such that they are level with each other. This processing may be performed by dry etching treatment or CMP treatment. Through this processing, the insulating film having the depressions becomes the base insulating film 302 having depressions, and the island-shaped semiconductor film becomes the pair of semiconductor layers 317 (see FIG. 9A).

Note that in this embodiment, the semiconductor film to be the pair of semiconductor layers 316 is processed into the island-shaped semiconductor film, and then the insulating film having the depressions and the island-shaped semiconductor film are processed such that they are level with each other; however, one embodiment of the present invention is not limited thereto. For example, the insulating film having the depressions the semiconductor film to be the pair of semiconductor layers 316 may be processed such that they are level with each other, and then the semiconductor film to be the pair of semiconductor layers 316 may be processed into island shapes.

For the details of the methods for forming the base insulating film 302 and the pair of semiconductor layers 317 filling the depressions of the base insulating film 302, refer to the methods for forming the base insulating film 202 and the pair of semiconductor layers 217 filling the depressions of the base insulating film 202 illustrated in FIGS. 7A to 7D.

Here, since the base insulating film 302 and the pair of semiconductor layers 317 are level with each other, a defect in shape of the layers formed through the subsequent steps can be prevented from being caused. Therefore, the transistor can have sable electric characteristics.

Then, a semiconductor film to be the semiconductor film 306 is formed. The semiconductor film to be the semiconductor film 306 may be any of the semiconductor films given as examples of the semiconductor film 306, and formed by a sputtering method, a CVD method, an MBE method, an ALD method, or a PLD method. The semiconductor film to be the semiconductor film 306 is preferably an oxide semiconductor film formed by a sputtering method. The reason why a sputtering method is preferable is that an oxide semiconductor film having high density and crystallinity can be easily formed. Further, the oxide semiconductor film is preferably formed while the substrate is heated at a temperature higher than or equal to 100° C. and lower than or equal to 450° C. because an oxide semiconductor film having high density and crystallinity can be easily formed.

After the oxide semiconductor film is formed, seventh heat treatment may be performed. The seventh heat treatment may be performed under the conditions described for the first heat treatment. By the seventh heat treatment, the crystallinity of the oxide semiconductor film can be improved, and in addition, impurities such as hydrogen and water can be removed from the oxide semiconductor film.

Next, the semiconductor film to be the semiconductor film 306 is processed into the island-shaped semiconductor film 306 (see FIG. 9B).

Next, an insulating film to be the gate insulating film 312 is formed. The insulating film to be the gate insulating film 312 may be any of the insulating films given as examples of the gate insulating film 312, and formed by a sputtering method, a CVD method, an MBE method, an ALD method, or a PLD method.

Next, a conductive film to be the gate electrode 304 is formed. The conductive film to be the gate electrode 304 may be any of the conductive films given as examples of the gate electrode 304, and formed by a sputtering method, a CVD method, an MBE method, an ALD method, or a PLD method.

Then, the conductive film to be the gate electrode 304 is processed to form the gate electrode 304.

Next, the insulating film to be the gate insulating film 312 is processed with the use of the resist mask used for the processing of the gate electrode 304 or with the use of the gate electrode 304 as a mask, whereby the gate insulating film 312 is formed (see FIG. 9C).

Next, impurities 330 generating carriers in the pair of semiconductor layers 317 are added to the pair of semiconductor layers 317 with the gate electrode 304 used as a mask (see FIG. 9D). As the impurities 330, any of the impurities described in the above embodiment may be used as appropriate. The impurities 330 may be added by an ion implantation method or an ion doping method. Preferably, an ion implantation method is used. At this time, the acceleration voltage is made higher than or equal to 5 kV and lower than or equal to 100 kV. The addition of the impurities 330 is performed such that the concentration of the impurities 330 in the pair of semiconductor layers 317 becomes higher than or equal to 1×10¹⁴ atoms/cm³ and lower than or equal to 1×10²¹ atoms/cm³, or higher than or equal to 1×10¹⁴ atoms/cm³ and lower than or equal to 1×10²⁰ atoms/cm³.

Next, eighth heat treatment may be performed. The eighth heat treatment may be performed under conditions selected from conditions similar to those of the first heat treatment. Through the eighth heat treatment, carriers are generated in regions to which the impurities 330 are added in the pair of semiconductor layers 317; thus, the regions 321b are formed. Note that regions to which the impurities 330 are not added in the pair of semiconductor layers 317 become regions 321a. In such a manner, a pair of semiconductor layers 321 each including the region 321a and the region 321b is formed (see FIG. 10A). In the case where the semiconductor film 306 is an oxide semiconductor film and the base insulating film 302 is an insulating film containing excess oxygen, defects in the semiconductor film 306 (oxygen vacancies in the oxide semiconductor film) can be reduced through the eighth heat treatment.

Next, an insulating film to be the sidewall insulating films 310 is formed. The insulating film to be the sidewall insulating films 310 may be any of the insulating films given as examples of the sidewall insulating films 310, and formed by a sputtering method, a CVD method, an MBE method, an ALD method, or a PLD method. Then, highly anisotropic etching treatment is performed on the insulating film to be the sidewall insulating films 310, whereby the sidewall insulating films 310 can be formed in contact with side surfaces of the gate insulating film 312 and the gate electrode 304 (see FIG. 10B).

Next, impurities 331 generating carriers in the pair of semiconductor layers 321 are added to the pair of semiconductor layers 321 with the gate electrode 304 and the sidewall insulating films 310 used as masks (see FIG. 10C). The impurities 331 are preferably, but not limited to, the same impurities as the impurities 330. As the impurities 331, any of the impurities described in the above embodiment may be used as appropriate. The impurities 331 may be added by an ion implantation method or an ion doping method. Preferably, an ion implantation method is used. At this time, the acceleration voltage is made higher than or equal to 5 kV and lower than or equal to 100 kV. The addition of the impurities 331 is performed such that the total concentration of the impurities 330 and the impurities 331 in the pair of semiconductor layers 321 becomes higher than or equal to 1×10¹⁶ atoms/cm³ and lower than or equal to 1×10²² atoms/cm³, or higher than or equal to 1×10¹⁸ atoms/cm³ and lower than or equal to 1×10²² atoms/cm³.

Next, ninth heat treatment is performed. The ninth heat treatment may be performed under conditions selected from conditions similar to those of the first heat treatment. Through the ninth heat treatment, carriers are generated in regions to which the impurities 331 are added in the pair of semiconductor layers 321; thus, the regions 316c are formed. Note that regions to which the impurities 330 are added and the impurities 331 are not added in the pair of semiconductor layers 321 become the regions 316b. Note that regions to which neither the impurities 330 nor the impurities 331 are added in the pair of semiconductor layers 321 become the regions 316a. In such a manner, the pair of semiconductor layers 316 is formed (see FIG. 10D). Here, the ninth heat treatment may double as the eighth heat treatment. In the case where the semiconductor film 306 is an oxide semiconductor film and the base insulating film 302 is an insulating film containing excess oxygen, defects in the semiconductor film 306 (oxygen vacancies in the oxide semiconductor film) can be reduced through the ninth heat treatment.

The impurities 330 and the impurities 331 are each added in the above manner, whereby two kinds of low-resistance regions can be provided in each of the pair of semiconductor layers 316. Consequently, concentration of an electric field can be easily relieved in the edge of the drain electrode and thus hot carrier degradation can be suppressed. The edge of the source electrode is less adversely affected by an electric field from the edge of the drain electrode, and DIBL can be suppressed.

Note that either the impurities 330 or the impurities 331 may be added. Specifically, the impurities 330 are not necessarily added. In that case, like the regions 316a, the regions 316b function as offset regions. When the regions 316b function as offset regions, concentration of an electric field is relieved in the vicinity of the channel region and thus hot carrier degradation can be suppressed. The edge of the source electrode is less adversely affected by an electric field from the edge of the drain electrode, and DIBL can be suppressed.

In the aforementioned manner, the transistor illustrated in FIG. 3A to 3C can be manufactured.

According to the method for manufacturing the transistor in FIGS. 3A to 3C described with reference to FIGS. 9A to 9D and FIGS. 10A to 10D, the pair of semiconductor layers 316 each including the region 316a, the region 316b, and the region 316c can be formed in such a manner that the impurities 330 are added to the pair of semiconductor layers 317 with the gate electrode 304 used as a mask, and then the impurities 331 are added to the pair of semiconductor layers 321 with the gate electrode 304 and the sidewall insulating films 310 used as masks. The regions 316c are low-resistance regions, and function as a source electrode and a drain electrode of the transistor. The regions 316b function as LDD regions or offset regions of the transistor. The region 316b and the region 316c are formed in a self-aligned manner; thus, the parasitic capacitance and parasitic resistance of the transistor can be reduced, and hot-carrier degradation and DIBL in the transistor can be reduced.

Next, the protective insulating film 318 is formed. The protective insulating film 318 may be any of the insulating films given as examples of the protective insulating film 318, and formed by a sputtering method, a CVD method, an MBE method, an ALD method, or a PLD method.

Then, the protective insulating film 318 is processed to form openings through which the pair of semiconductor layers 316 is exposed.

Next, a conductive film to be the wiring 324a and the wiring 324b is formed. The conductive film to be the wiring 324a and the wiring 324b may be any of the conductive films given as examples of the wiring 324a and the wiring 324b, and formed by a sputtering method, a CVD method, an MBE method, an ALD method, or a PLD method.

The conductive film to be the wiring 324a and the wiring 324b is processed, whereby the wiring 324a and the wiring 324b are formed.

In the case where the pair of semiconductor layers 316 contains silicon, tenth heat treatment may be performed after the conductive film to be the wirings 324a and 324b is formed so that silicide is formed in portions where the pair of semiconductor layers 316 is in contact with the conductive film to be the wirings 324a and 324b. With silicide, the contact resistance between the pair of semiconductor layers 316 and the wirings 324a and 324b can be reduced. Consequently, the parasitic resistance of the transistor can be reduced, and the on-state current of the transistor can be increased. The tenth heat treatment may be performed under conditions selected from conditions similar to those of the first heat treatment.

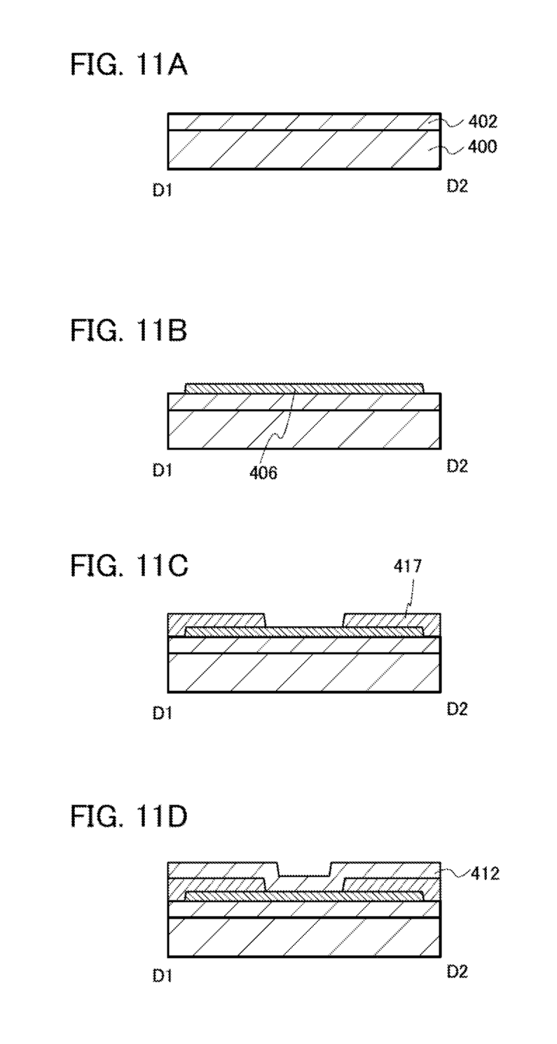

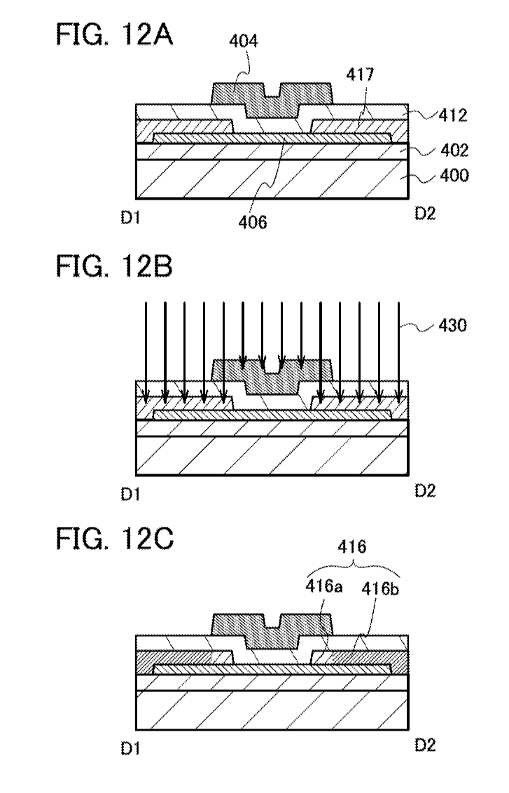

Next, a method for manufacturing the transistor illustrated in FIGS. 4A to 4C will be described with reference to FIGS. 11A to 11D and FIGS. 12A to 12C. Note that for easy understanding, FIGS. 11A to 11D and FIGS. 12A to 12C only illustrate cross-sectional views of the transistor corresponding to FIG. 4B.

First, the substrate 400 is prepared. As the substrate 400, any of the substrates given as examples of the substrate 400 can be used.

Next, the base insulating film 402 is formed (see FIG. 11A). The base insulating film 402 may be any of the insulating films given as examples of the base insulating film 402, and formed by a sputtering method, a CVD method, an MBE method, an ALD method, or a PLD method.

For example, a silicon oxide film is preferably formed as the base insulating film 402 by an RF sputtering method using a quartz (preferably synthetic quartz) target under the following conditions: the substrate heating temperature is higher than or equal to 30° C. and lower than or equal to 450° C. (preferably higher than or equal to 70° C. and lower than or equal to 200° C.); the distance between the substrate and the target (the T-S distance) is longer than or equal to 20 mm and shorter than or equal to 400 mm (preferably longer than or equal to 40 mm and shorter than or equal to 200 mm); the pressure is higher than or equal to 0.1 Pa and lower than or equal to 4 Pa (preferably higher than or equal to 0.2 Pa and lower than or equal to 1.2 Pa); the high-frequency power source is higher than or equal to 0.5 kW and lower than or equal to 12 kW (preferably higher than or equal to 1 kW and lower than or equal to 5 kW); and the proportion of O₂/(O₂+Ar) in the deposition gas is higher than or equal to 20% and lower than or equal to 100% (preferably higher than or equal to 50% and lower than or equal to 100%). Note that a silicon target may be used as the target instead of the quartz (preferably synthetic quartz) target. Note that an oxygen gas or a mixed gas of oxygen and argon is used as the deposition gas. With the use of such a method, the base insulating film 402 can be an insulating film containing excess oxygen.

Then, a semiconductor film to be the semiconductor film 406 is formed. The semiconductor film to be the semiconductor film 406 may be any of the semiconductor films given as examples of the semiconductor film 406, and formed by a sputtering method, a CVD method, an MBE method, an ALD method, or a PLD method. The semiconductor film to be the semiconductor film 406 is preferably an oxide semiconductor film formed by a sputtering method. The reason why a sputtering method is preferable is that an oxide semiconductor film having high density and crystallinity can be easily formed. Further, the oxide semiconductor film is preferably formed while the substrate is heated at a temperature higher than or equal to 400° C. and lower than or equal to 450° C. because an oxide semiconductor film having high density and crystallinity can be easily formed.

After the oxide semiconductor film is formed, eleventh heat treatment may be performed. The eleventh heat treatment may be performed under the conditions described for the first heat treatment. By the eleventh heat treatment, the crystallinity of the oxide semiconductor film can be improved, and in addition, impurities such as hydrogen and water can be removed from the oxide semiconductor film.

Next, the semiconductor film to be the semiconductor film 406 is processed into the island-shaped semiconductor film 406 (see FIG. 11B).

Note that in the case where the semiconductor film 406 is an oxide semiconductor film, twelfth heat treatment may be performed after the semiconductor film 406 is formed. The twelfth heat treatment may be performed under the conditions described for the first heat treatment. Since the twelfth heat treatment is performed with side surfaces of the oxide semiconductor exposed, impurities such as hydrogen and water are easily removed from the side surfaces of the oxide semiconductor film; thus, impurities can be effectively removed. Note that in the case where the oxide semiconductor film is a CAAC-OS film, impurities are easily diffused along a layer of crystals; thus, impurities such as hydrogen and water are more easily removed from the side surfaces of the oxide semiconductor film.

Then, a semiconductor film to be the pair of semiconductor layers 416 is formed. The semiconductor film to be the pair of semiconductor layers 416 may be any of the semiconductor layers given as examples of the pair of semiconductor layers 416, and formed by a sputtering method, a CVD method, an MBE method, an ALD method, or a PLD method.

Next, the semiconductor film to be the pair of semiconductor layers 416 is processed to form a pair of semiconductor layers 417 (see FIG. 11C).

Next, the gate insulating film 412 is formed (see FIG. 11D). The gate insulating film 412 may be any of the insulating films given as examples of the gate insulating film 412, and formed by a sputtering method, a CVD method, an MBE method, an ALD method, or a PLD method.

Then, a conductive film to be the gate electrode 404 is formed. The conductive film to be the gate electrode 404 may be any of the conductive films given as examples of the gate electrode 404, and formed by a sputtering method, a CVD method, an MBE method, an ALD method, or a PLD method.

After that, the conductive film to be the gate electrode 404 is processed, whereby the gate electrode 404 is formed (see FIG. 12A).

Next, impurities 430 generating carriers in the pair of semiconductor layers 417 are added to the pair of semiconductor layers 417 with the gate electrode 404 used as a mask (see FIG. 12B). As the impurities 430, any of the impurities described in the above embodiment may be used as appropriate. The impurities 430 may be added by an ion implantation method or an ion doping method. Preferably, an ion implantation method is used. At this time, the acceleration voltage is made higher than or equal to 5 kV and lower than or equal to 400 kV. The addition of the impurities 430 is performed such that the concentration of the impurities 430 in the pair of semiconductor layers 417 becomes higher than or equal to 1×10¹⁴ atoms/cm³ and lower than or equal to 1×10²² atoms/cm³, or higher than or equal to 1×10¹⁶ atoms/cm³ and lower than or equal to 1×10²¹ atoms/cm³.

Next, thirteenth heat treatment is performed. The thirteenth heat treatment may be performed under conditions selected from conditions similar to those of the first heat treatment. Through the thirteenth heat treatment, carriers are generated in regions to which the impurities 430 are added in the pair of semiconductor layers 417; thus, the regions 416b are formed. Note that regions to which the impurities 430 are not added in the pair of semiconductor layers 417 become the regions 416a (see FIG. 12C). In the case where the semiconductor film 406 is an oxide semiconductor film and the base insulating film 402 is an insulating film containing excess oxygen, defects in the semiconductor film 406 (oxygen vacancies in the oxide semiconductor film) can be reduced through the thirteenth heat treatment.

In the aforementioned manner, the transistor illustrated in FIGS. 4A to 4C can be manufactured.

According to the method for manufacturing the transistor in FIGS. 1A to 1C described with reference to FIGS. 11A to 11D and FIGS. 12A to 12C, the pair of semiconductor layers 416 each including the region 416a and the region 416b can be formed in such a manner that the impurities 430 are added to the pair of semiconductor layers 417 with the gate electrode 404 used as a mask. The regions 416b are low-resistance regions, and function as a source electrode and a drain electrode of the transistor. The regions 416b are formed in a self-aligned manner; thus, the parasitic capacitance and parasitic resistance of the transistor can be reduced.

The methods for manufacturing the transistors described above can be combined with each other as appropriate.

By application of any of the methods for manufacturing the transistors in this embodiment, a pair of semiconductor layers functioning as a source electrode and a drain electrode can be formed in a self-aligned manner; thus, a transistor having low parasitic resistance and small parasitic capacitance can be manufactured.

This embodiment is obtained by performing change, addition, modification, removal, application, superordinate conceptualization, or subordinate conceptualization on part or the whole of another embodiment. Thus, part or the whole of this embodiment can be freely combined with, applied to, or replaced with part or the whole of another embodiment.

### Embodiment 3

In this embodiment, a display device to which any of the transistors described in the above embodiment is applied will be described.

As a display element provided in the display device, a liquid crystal element (also referred to as liquid crystal display element) or a light-emitting element (also referred to as light-emitting display element) can be used. The light-emitting element includes, in its category, an element whose luminance is controlled by current or voltage, and specifically includes, in its category, an inorganic electroluminescent (EL) element, an organic EL element, and the like. Furthermore, a display medium whose contrast is changed by an electric effect, such as electronic ink, can be used as the display element. In this embodiment, a display device using an EL element and a display device using a liquid crystal element will be described as examples of the display device.

Note that the display device in this embodiment includes a panel in which a display element is sealed and a module in which an IC and the like including a controller are mounted on the panel.

The display device in this embodiment means an image display device, a display device, or a light source (including a lighting device). Furthermore, the display device also includes the following modules: a module to which a connector such as an FPC or a TCP is attached; a module having a TCP at the tip of which a printed wiring board is provided; and a module in which an integrated circuit (IC) is directly mounted on a display element by a COG method.

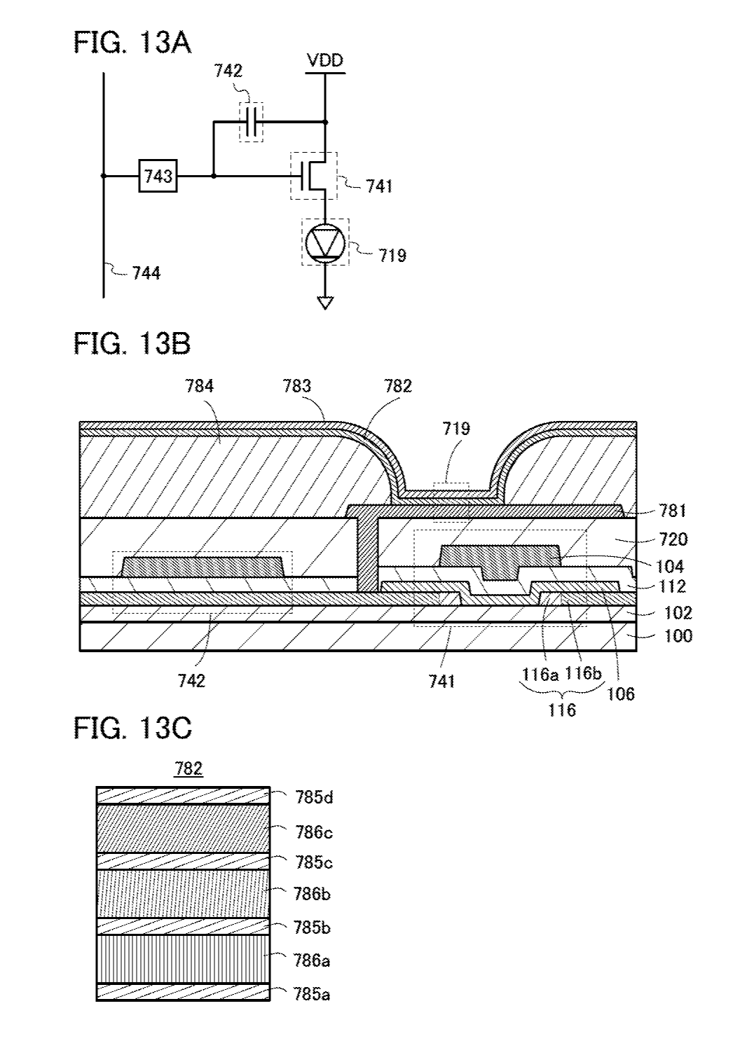

FIG. 13A illustrates an example of a circuit diagram of a display device using an EL element.

The display device illustrated in FIG. 13A includes a switch element 743, a transistor 741, a capacitor 742, and a light-emitting element 719.

A gate of the transistor 741 is electrically connected to one terminal of the switch element 743 and one terminal of the capacitor 742. A source of the transistor 741 is electrically connected to one terminal of the light-emitting element 719. A drain of the transistor 741 is electrically connected to the other terminal of the capacitor 742, and is supplied with a power supply potential VDD. The other terminal of the switch element 743 is electrically connected to a signal line 744. The other terminal of the light-emitting element 719 is supplied with a fixed potential. Note that the fixed potential is lower than or equal to a ground potential GND.

As the transistor 741, any of the transistors described in the above embodiment is used. The transistor has low parasitic resistance and small parasitic capacitance. Consequently, a display device having high display quality can be achieved.

As the switch element 743, a transistor is preferably used. With the use of the transistor as the switch element 743, the area of a pixel can be reduced, and the resolution of the display device can be improved. Note that as the switch element 743, any of the transistors described in the above embodiment may be used, in which case the switch element 743 can be manufactured through the same process as the transistor 741; thus, the productivity in manufacturing display devices can be improved.

FIG. 13B illustrates part of a cross section of a pixel including the transistor 741, the capacitor 742, and the light-emitting element 719.

Note that FIG. 13B shows an example where the transistor 741 and the capacitor 742 are provided in the same plane. With this structure, the capacitor 742 can be formed using the same layers and the same materials as the gate electrode, a gate insulating film, and the pair of semiconductor layers 116 functioning as a source electrode and a drain electrode of the transistor 741. For such a reason, the pair of semiconductor layers 116 in the capacitor 742 may be part of or separate from the pair of semiconductor layers 116 functioning as the source electrode and the drain electrode of the transistor 741. When the transistor 741 and the capacitor 742 are provided in the same plane in this manner, the number of manufacturing steps of a display device can be reduced and thus the productivity can be improved.

In the example of FIG. 13B, the transistor illustrated in FIGS. 1A to 1C is used as the transistor 741. Therefore, for components of the transistor 741 which are not particularly described below, refer to the description in the above embodiment.

An insulating film 720 is provided over the transistor 741 and the capacitor 742.

Here, an opening reaching one of the pair of semiconductor layers 116 in the transistor 741 is provided in the insulating film 720.

An electrode 781 is provided over the insulating film 720. The electrode 781 is in contact with the one of the pair of semiconductor layers 116 in the transistor 741 through the opening provided in the insulating film 720.

Over the electrode 781, a bank 784 having an opening reaching the electrode 781 is provided.

Over the bank 784, a light-emitting layer 782 in contact with the electrode 781 through the opening in the bank 784 is provided.

An electrode 783 is provided over the light-emitting layer 782.

A region where the electrode 781, the light-emitting layer 782, and the electrode 783 overlap with one another serves as the light-emitting element 719.

The insulating film 720 may be formed of a single layer or a stacked layer using an insulating film containing one or more of aluminum oxide, magnesium oxide, silicon oxide, silicon oxynitride, silicon nitride oxide, silicon nitride, germanium oxide, yttrium oxide, zirconium oxide, lanthanum oxide, neodymium oxide, hafnium oxide, and tantalum oxide. Alternatively, a resin film of a polyimide resin, an acrylic resin, an epoxy resin, a silicone resin, or the like may be used.

The light-emitting layer 782 is not limited to a single layer, and may be a stack of a plurality of kinds of light-emitting materials. For example, a structure illustrated in FIG. 13C may be employed. FIG. 13C illustrates the structure in which an intermediate layer 785a, a light-emitting layer 786a, an intermediate layer 785b, a light-emitting layer 786b, an intermediate layer 785c, a light-emitting layer 786c, and an intermediate layer 785d are stacked in this order. In this case, when materials emitting light of appropriate colors are used for the light-emitting layer 786a, the light-emitting layer 786b, and the light-emitting layer 786c, the light-emitting element 719 with a high color rending property or high emission efficiency can be formed.

White light may be obtained by stacking a plurality of kinds of light-emitting materials. Although not illustrated in FIG. 13B, white light may be extracted through coloring layers.

Although the structure in which three light-emitting layers and four intermediate layers are provided is shown here, the number of light-emitting layers and the number of intermediate layers can be changed as appropriate. For example, the light-emitting layer 782 can be formed with only the intermediate layer 785a, the light-emitting layer 786a, the intermediate layer 785b, the light-emitting layer 786b, and the intermediate layer 785c. Alternatively, the light-emitting layer 782 may be formed with the intermediate layer 785a, the light-emitting layer 786a, the intermediate layer 785b, the light-emitting layer 786b, the light-emitting layer 786c, and the intermediate layer 785d, and the intermediate layer 785c may be omitted.

Further, the intermediate layer may have a stacked-layer structure including any of a hole-injection layer, a hole-transport layer, an electron-transport layer, an electron-injection layer, and the like. Note that not all of these layers need to be provided as the intermediate layer. Any of these layers may be selected as appropriate to form the intermediate layer. Note that layers having similar functions may be provided. Further, an electron-relay layer or the like may be added as appropriate as the intermediate layer, in addition to a carrier generation layer.

The electrode 781 may be formed using a conductive film having a transmitting property with respect to visible light. The phrase “having a transmitting property with respect to visible light” means that the average transmittance of light in a visible light region (for example, a wavelength range from 400 nm to 800 nm) is higher than or equal to 70%, particularly higher than or equal to 80%.

As the electrode 781, for example, an oxide film such as an In—Zn—W-based oxide film, an In—Sn-based oxide film, an In—Zn-based oxide film, an In-based oxide film, a Zn-based oxide film, or a Sn-based oxide film may be used. The above oxide film may contain a minute amount of Al, Ga, Sb, F, or the like. Further, a metal thin film having a thickness small enough to transmit light (preferably, approximately 5 nm to 30 nm) can also be used. For example, an Ag film, an Mg film, or an Ag—Mg alloy film with a thickness of 5 nm may be used.

The electrode 781 is preferably a film which efficiently reflects visible light. For example, a film containing lithium, aluminum, titanium, magnesium, lanthanum, silver, silicon, or nickel may be used as the electrode 781.

The electrode 783 can be formed using any of the films for the electrode 781. Note that when the electrode 781 has a transmitting property with respect to visible light, it is preferable that the electrode 783 efficiently reflect visible light. When the electrode 781 efficiently reflects visible light, it is preferable that the electrode 783 have a transmitting property with respect to visible light.

Positions of the electrode 781 and the electrode 783 are not limited to the structure illustrated in FIG. 13B, and the electrode 781 and the electrode 783 may be replaced with each other. It is preferable to use a conductive film having a high work function for the electrode which functions as an anode, and a conductive film having a low work function for the electrode which functions as a cathode. Note that in the case where a carrier generation layer is provided in contact with the anode, a variety of conductive films can be used for the anode regardless of their work functions.

The bank 784 may be formed of a single layer or a stacked layer using an insulating film containing one or more of aluminum oxide, magnesium oxide, silicon oxide, silicon oxynitride, silicon nitride oxide, silicon nitride, germanium oxide, yttrium oxide, zirconium oxide, lanthanum oxide, neodymium oxide, hafnium oxide, and tantalum oxide. Alternatively, a resin film of a polyimide resin, an acrylic resin, an epoxy resin, a silicone resin, or the like may be used.

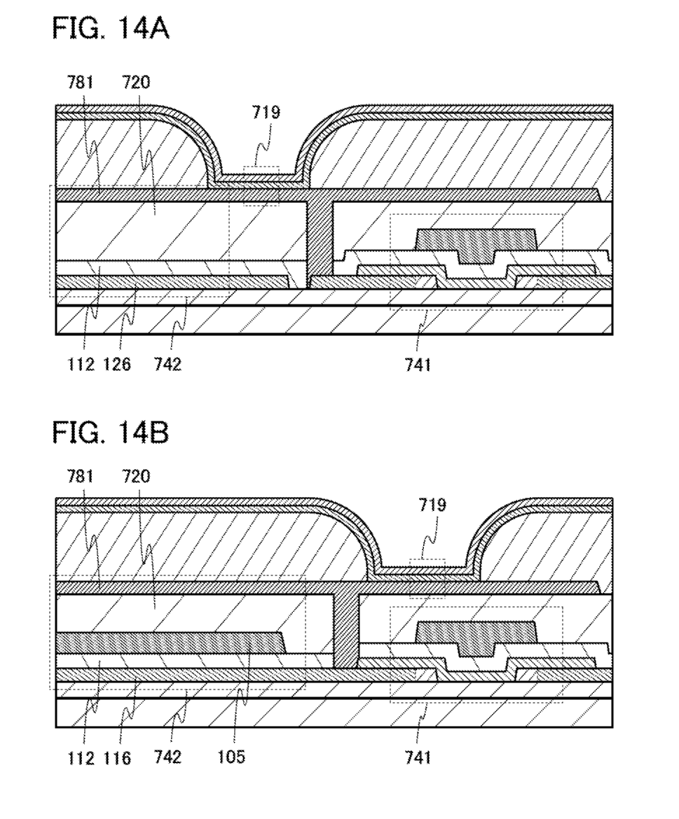

FIGS. 14A and 14B each show an example where the structure of the capacitor 742 in FIG. 13A is different from that in FIG. 13B.

In FIG. 14A, the capacitor 742 includes an electrode 126, the gate insulating film 112 over the electrode 126, the insulating film 720 over the gate insulating film 112, and the electrode 781 over the insulating film 720. Note that the electrode 126 may be formed through the same steps as the pair of semiconductor layers 116. When the electrode 781, the gate insulating film 112, the insulating film 720, and the pair of semiconductor layers 116 each have a transmitting property with respect to visible light, the capacitor 742 has a transmitting property with respect to visible light. Therefore, the aperture ratio of the display device can be improved in some cases. Further, the display quality of the display device can be improved in some cases.

In FIG. 14B, the capacitor 742 includes one of the pair of semiconductor layers 116; the gate insulating film 112 over the one of the pair of semiconductor layers 116; an electrode 105 over the gate insulating film 112; the insulating film 720 over the electrode 105; and the electrode 781 over the insulating film 720. Note that the electrode 105 may be formed through the same steps as the gate electrode 104. In this structure, the capacitor 742 has a first capacitor and a second capacitor. The first capacitor includes the electrode 105, the gate insulating film 112, and the one of the pair of semiconductor layers 116. The second capacitor includes the electrode 105, the insulating film 720, and the electrode 781. Therefore, the capacitor 742 illustrated in FIG. 14B can have a large capacitance with a small area. Therefore, the aperture ratio of the display device can be improved in some cases. Further, the display quality of the display device can be improved in some cases.

In the capacitor 742 illustrated in FIG. 14B, the one of the pair of semiconductor layers 116 and the electrode 781 do not necessarily overlap with each other.

The transistor 741 connected to the light-emitting element 719 has low parasitic resistance and small parasitic capacitance. Consequently, a display device having high display quality can be achieved.

Next, a display device using a liquid crystal element will be described.

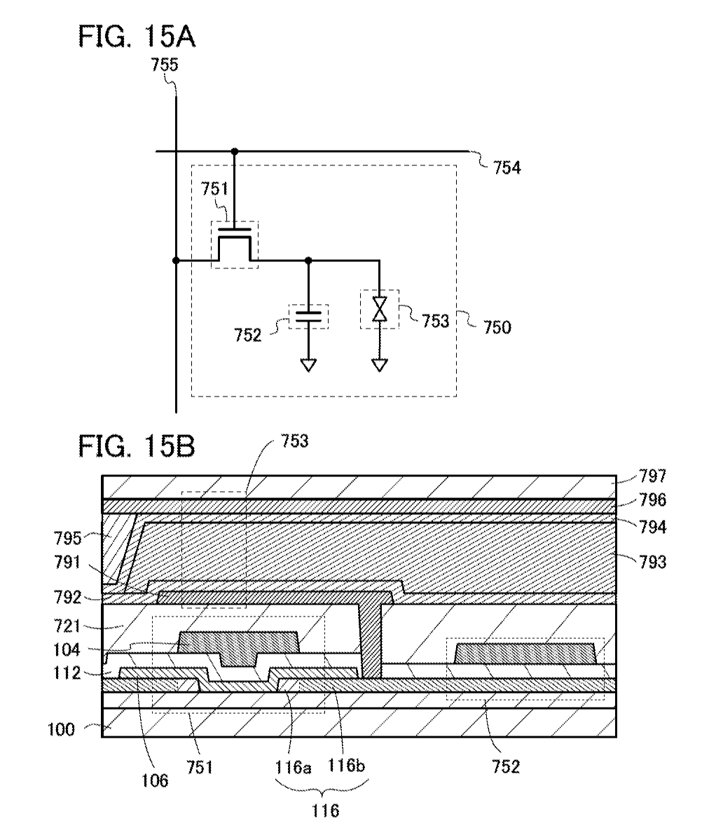

FIG. 15A is a circuit diagram illustrating a structure example of a pixel of a display device using a liquid crystal element. A pixel 750 in FIG. 15A includes a transistor 751, a capacitor 752, and an element in which a liquid crystal material is filled between a pair of electrodes (hereinafter also referred to as a liquid crystal element) 753.

One of a source and a drain of the transistor 751 is electrically connected to a signal line 755, and a gate of the transistor 751 is electrically connected to a scan line 754.

One of electrodes of the capacitor 752 is electrically connected to the other of the source and the drain of the transistor 751, and the other of the electrodes of the capacitor 752 is electrically connected to a wiring for supplying a common potential.

One of electrodes of the liquid crystal element 753 is electrically connected to the other of the source and the drain of the transistor 751, and the other of the electrodes of the liquid crystal element 753 is electrically connected to a wiring for supplying a common potential. Note that the common potential supplied to the other of the electrodes of the liquid crystal element 753 may be different from the common potential supplied to the wiring electrically connected to the other of the electrodes of the capacitor 752.

FIG. 15B illustrates part of a cross section of the pixel 750.

Note that FIG. 15B shows an example where the transistor 751 and the capacitor 752 are provided in the same plane. With this structure, the capacitor 752 can be formed using the same layers and the same materials as the gate electrode, a gate insulating film, and the pair of semiconductor layers 116 functioning as a source electrode and a drain electrode of the transistor 751. For such a reason, the pair of semiconductor layers 116 in the capacitor 752 may be part of or separate from the pair of semiconductor layers 116 functioning as the source electrode and the drain electrode of the transistor 751. When the transistor 751 and the capacitor 752 are provided in the same plane in this manner, the number of manufacturing steps of a display device can be reduced and thus the productivity can be improved.

As the transistor 751, any of the transistors described in the above embodiment can be used. In the example of FIG. 15B, the transistor illustrated in FIGS. 1A to 1C is used. Therefore, for components of the transistor 751 which are not particularly described below, refer to the description in the above embodiment.

Note that in the case where an oxide semiconductor film is used as the semiconductor film 106 of the transistor 751, the off-state current of the transistor 751 can be extremely small. Consequently, a charge held in the capacitor 752 is unlikely to leak, and a voltage applied to the liquid crystal element 753 can be kept for a long period. Therefore, by turning off the transistor 751 when an image with little motion or a still image is displayed, a voltage for operating the transistor 751 is unnecessary. As a result, the power consumption of the display device can be lower.

An insulating film 721 is provided over the transistor 751 and the capacitor 752.

Here, an opening reaching one of the pair of semiconductor layers 116 in the transistor 751 is provided in the insulating film 721.

An electrode 791 is provided over the insulating film 721. The electrode 791 is in contact with the one of the pair of semiconductor layers 116 in the transistor 751 through the opening provided in the insulating film 721.

Over the electrode 791, an insulating film 792 functioning as an alignment film is provided.

A liquid crystal layer 793 is provided over the insulating film 792.

An insulating film 794 functioning as an alignment film is provided over the liquid crystal layer 793.

A spacer 795 is provided over the insulating film 794.

An electrode 796 is provided over the spacer 795 and the insulating film 794.

A substrate 797 is provided over the electrode 796.

The insulating film 721 may be formed of a single layer or a stacked layer using an insulating film containing one or more of aluminum oxide, magnesium oxide, silicon oxide, silicon oxynitride, silicon nitride oxide, silicon nitride, germanium oxide, yttrium oxide, zirconium oxide, lanthanum oxide, neodymium oxide, hafnium oxide, and tantalum oxide. Alternatively, a resin film of a polyimide resin, an acrylic resin, an epoxy resin, a silicone resin, or the like may be used.

For the liquid crystal layer 793, a thermotropic liquid crystal, a low-molecular liquid crystal, a polymer liquid crystal, a polymer-dispersed liquid crystal, a ferroelectric liquid crystal, an anti-ferroelectric liquid crystal, or the like may be used. Such a liquid crystal material exhibits a cholesteric phase, a smectic phase, a cubic phase, a chiral nematic phase, an isotropic phase, or the like depending on conditions.

For the liquid crystal layer 793, a liquid crystal material exhibiting a blue phase may be used. In that case, the insulating films 792 and 794 functioning as the alignment films are not necessarily provided.

The electrode 791 may be formed using a conductive film having a transmitting property with respect to visible light.

As the electrode 791, for example, an oxide film such as an In—Zn—W-based oxide film, an In—Sn-based oxide film, an In—Zn-based oxide film, an In-based oxide film, a Zn-based oxide film, or a Sn-based oxide film may be used. The above oxide film may contain a minute amount of Al, Ga, Sb, F, or the like. Further, a metal thin film having a thickness small enough to transmit light (preferably, approximately 5 nm to 30 nm) can also be used.

The electrode 791 is preferably a film which efficiently reflects visible light. For example, a film containing aluminum, titanium, chromium, copper, molybdenum, silver, tantalum, or tungsten may be used as the electrode 791.

The electrode 796 can be formed using any of the films for the electrode 791. Note that when the electrode 791 has a transmitting property with respect to visible light, it is preferable that the electrode 796 efficiently reflect visible light. When the electrode 791 efficiently reflects visible light, it is preferable that the electrode 796 have a transmitting property with respect to visible light.

Positions of the electrode 791 and the electrode 796 are not limited to the structure illustrated in FIG. 15B, and the electrode 791 and the electrode 796 may be replaced with each other.

Each of the insulating films 792 and 794 may be formed using an organic compound film or an inorganic compound film.

The spacer 795 may be formed using an organic compound or an inorganic compound. Note that the spacer 795 can have a variety of shapes such as a columnar shape and a spherical shape.

A region where the electrode 791, the insulating film 792, the liquid crystal layer 793, the insulating film 794, and the electrode 796 overlap with one another functions as the liquid crystal element 753.

For the substrate 797, a glass, a resin, a metal, or the like may be used. The substrate 797 may be a flexible substrate.

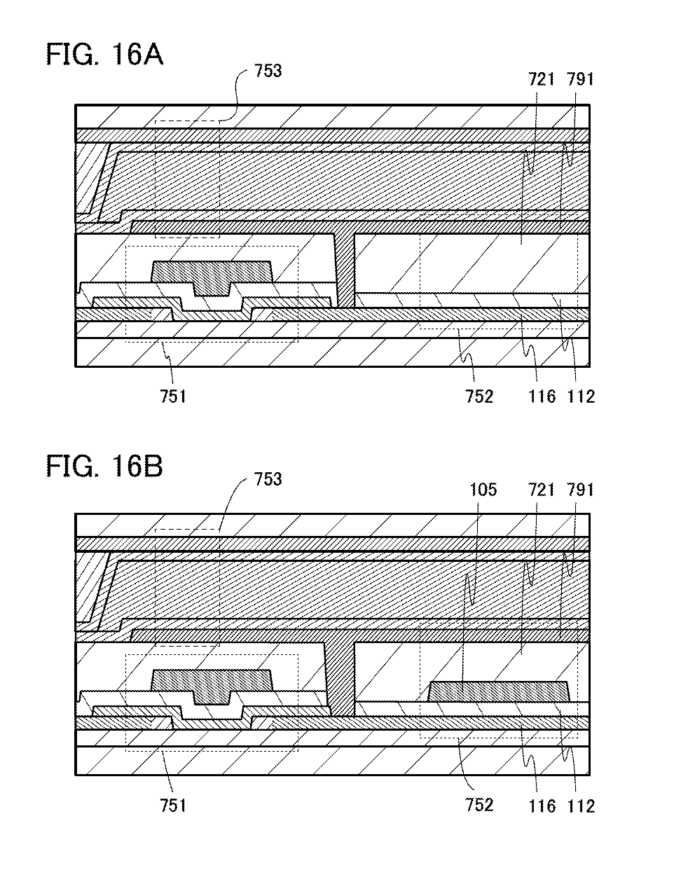

FIGS. 16A and 16B each show an example where the structure of the capacitor 752 in FIG. 15A is different from that in FIG. 15B.

In FIG. 16A, the capacitor 752 includes the pair of semiconductor layers 116, the gate insulating film 112 over the pair of semiconductor layers 116, the insulating film 721 over the gate insulating film 112, and the electrode 791 over the insulating film 721. When the electrode 791, the gate insulating film 112, the insulating film 721, and the pair of semiconductor layers 116 each have a transmitting property with respect to visible light, the capacitor 752 has a transmitting property with respect to visible light. Therefore, the aperture ratio of the display device can be improved in some cases. Further, the display quality of the display device can be improved in some cases.

In FIG. 16B, the capacitor 752 includes one of the pair of semiconductor layers 116; the gate insulating film 112 over the one of the pair of semiconductor layers 116; the electrode 105 over the gate insulating film 112; the insulating film 721 over the electrode 105; and the electrode 791 over the insulating film 721. Note that the electrode 105 may be formed through the same steps as the gate electrode 104. In this structure, the capacitor 752 has a first capacitor and a second capacitor. The first capacitor includes the electrode 105, the gate insulating film 112, and the one of the pair of semiconductor layers 116. The second capacitor includes the electrode 105, the insulating film 721, and the electrode 791. Therefore, the capacitor 752 illustrated in FIG. 16B can have a large capacitance with a small area. Therefore, the aperture ratio of the display device can be improved in some cases. Further, the display quality of the display device can be improved in some cases.

In the capacitor 752 illustrated in FIG. 16B, the one of the pair of semiconductor layers 116 and the electrode 791 do not necessarily overlap with each other.

The transistor 751 connected to the liquid crystal element 753 has low parasitic resistance and small parasitic capacitance. Consequently, a display device having high display quality can be achieved. With the use of an oxide semiconductor film as the semiconductor film 106 of the transistor 751, a display device with low power consumption can be provided.

This embodiment is obtained by performing change, addition, modification, removal, application, superordinate conceptualization, or subordinate conceptualization on part or the whole of another embodiment. Thus, part or the whole of this embodiment can be freely combined with, applied to, or replaced with part or the whole of another embodiment.

### Embodiment 4

In this embodiment, a semiconductor device which includes any of the transistors described in the above embodiment will be described. As the semiconductor film in the transistor, an oxide semiconductor film is used.

With the use of an oxide semiconductor film, the off-state current of the transistor described in the above embodiment can be extremely small. That is, charge is unlikely to leak through the transistor.

A semiconductor device which includes a transistor having such electric characteristics will be described below. The semiconductor device includes a memory element which is superior in function to a known memory element.

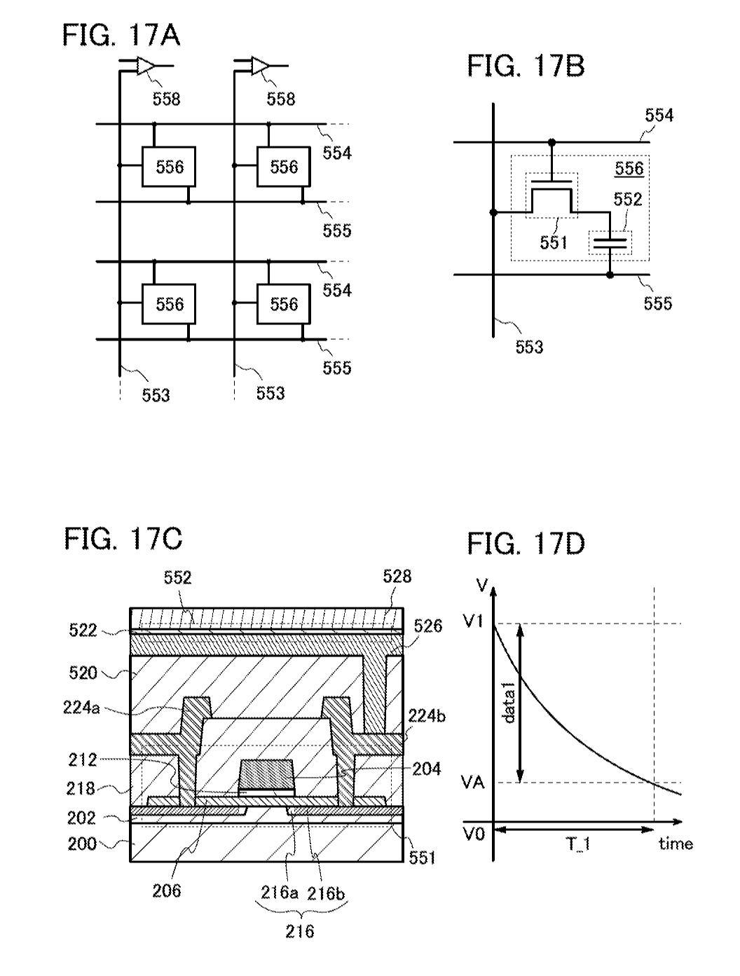

First, the semiconductor device will be specifically described with reference to FIGS. 17A to 17D. FIG. 17A is a circuit diagram showing a memory cell array of the semiconductor device. FIG. 17B is a circuit diagram of a memory cell. FIG. 17C illustrates an example of a cross-sectional structure corresponding to the memory cell in FIG. 17B. FIG. 17D is a graph showing electric characteristics of the memory cell in FIG. 17B.

The memory cell array in FIG. 17A includes a plurality of memory cells 556, a plurality of bit lines 553, a plurality of word lines 554, a plurality of capacitor lines 555, and a plurality of sense amplifiers 558.

Note that the bit lines 553 and the word lines 554 are provided in a grid pattern, and the memory cell 556 is provided for each intersection of the bit line 553 and the word line 554. The bit lines 553 are connected to the respective sense amplifiers 558. The sense amplifiers 558 have a function of reading the potentials of the bit lines 553 as data.

As shown in FIG. 17B, the memory cell 556 includes a transistor 551 and a capacitor 552. A gate of the transistor 551 is electrically connected to the word line 554. A source of the transistor 551 is electrically connected to the bit line 553. A drain of the transistor 551 is electrically connected to one terminal of the capacitor 552. The other terminal of the capacitor 552 is electrically connected to the capacitor line 555.

FIG. 17C illustrates an example of a cross-sectional structure of the memory cell. FIG. 17C is a cross-sectional view of the semiconductor device including the transistor 551, the wirings 224a and 224b connected to the transistor 551, an insulating film 520 over the transistor 551 and the wirings 224a and 224b, and the capacitor 552 over the insulating film 520.

In FIG. 17C, the transistor illustrated in FIGS. 2A to 2C is used as the transistor 551. Therefore, for components of the transistor 551 which are not particularly described below, refer to the description in the above embodiment. The case where an oxide semiconductor film is used as the semiconductor film 206 in the transistor 551 is described below.

The insulating film 520 may be formed of a single layer or a stacked layer using an insulating film containing one or more of aluminum oxide, magnesium oxide, silicon oxide, silicon oxynitride, silicon nitride oxide, silicon nitride, germanium oxide, yttrium oxide, zirconium oxide, lanthanum oxide, neodymium oxide, hafnium oxide, and tantalum oxide. Alternatively, a resin film of a polyimide resin, an acrylic resin, an epoxy resin, a silicone resin, or the like may be used as the insulating film 520.

The capacitor 552 includes an electrode 526 in contact with the wiring 224b; an electrode 528 overlapping with the electrode 526; and an insulating film 522 sandwiched between the electrode 526 and the electrode 528.

The electrode 526 may be formed of a single layer or a stacked layer using one or more conductive films containing a simple substance selected from Al, Ti, Cr, Co, Ni, Cu, Y, Zr, Mo, Ag, Ta, and W; a nitride containing one or more kinds of the above substances; an oxide containing one or more kinds of the above substances; or an alloy containing one or more kinds of the above substances.

The electrode 528 may be formed of a single layer or a stacked layer using one or more conductive films containing a simple substance selected from Al, Ti, Cr, Co, Ni, Cu, Y, Zr, Mo, Ag, Ta, and W; a nitride containing one or more kinds of the above substances; an oxide containing one or more kinds of the above substances; or an alloy containing one or more kinds of the above substances.

The insulating film 522 may be formed of a single layer or a stacked layer using an insulating film containing one or more of aluminum oxide, magnesium oxide, silicon oxide, silicon oxynitride, silicon nitride oxide, silicon nitride, germanium oxide, yttrium oxide, zirconium oxide, lanthanum oxide, neodymium oxide, hafnium oxide, and tantalum oxide.

In the example of FIG. 17C, the transistor 551 and the capacitor 552 are provided in different layers so as to overlap with each other; however, one embodiment of the present invention is not limited to this structure. For example, the transistor 551 and the capacitor 552 may be provided in the same layer. With such a structure, memory cells having similar structures can be disposed so as to overlap with each other, in which case, a large number of memory cells can be integrated in an area for one memory cell. Accordingly, the degree of integration of the semiconductor device can be improved. Note that in this specification, “A overlaps with B” means that A and B are provided such that at least part of A overlaps with at least part of B.

Here, the wiring 224a in FIG. 17C is electrically connected to the bit line 553 in FIG. 17B. The gate electrode 204 in FIG. 17C is electrically connected to the word line 554 in FIG. 17B. The electrode 528 in FIG. 17C is electrically connected to the capacitor line 555 in FIG. 17B.

As shown in FIG. 17D, a voltage held in the capacitor 552 gradually decreases with time due to leakage through the transistor 551. A voltage originally charged from V0 to V1 is decreased with time to VA that is a limit for reading out data 1. This period is called a holding period T_1. In the case of a two-level memory cell, refresh operation needs to be performed within the holding period T_1.

For example, in the case where the off-state current of the transistor 551 is not sufficiently small, the holding period T_1 becomes short because the voltage held in the capacitor 552 significantly changes with time. Accordingly, refresh operation needs to be frequently performed. An increase in frequency of refresh operation increases power consumption of the semiconductor device.

Since the off-state current of the transistor 551 is extremely small in this embodiment, the holding period T_1 can be made extremely long. That is, the frequency of refresh operation can be reduced; thus, power consumption can be reduced. For example, in the case where a memory cell is formed using the transistor 551 having an off-state current of 1×10⁻²¹ A to 1×10⁻²⁵ A, data can be held for several days to several decades without supply of electric power.

As described above, according to one embodiment of the present invention, a semiconductor device with high degree of integration and low power consumption can be provided.

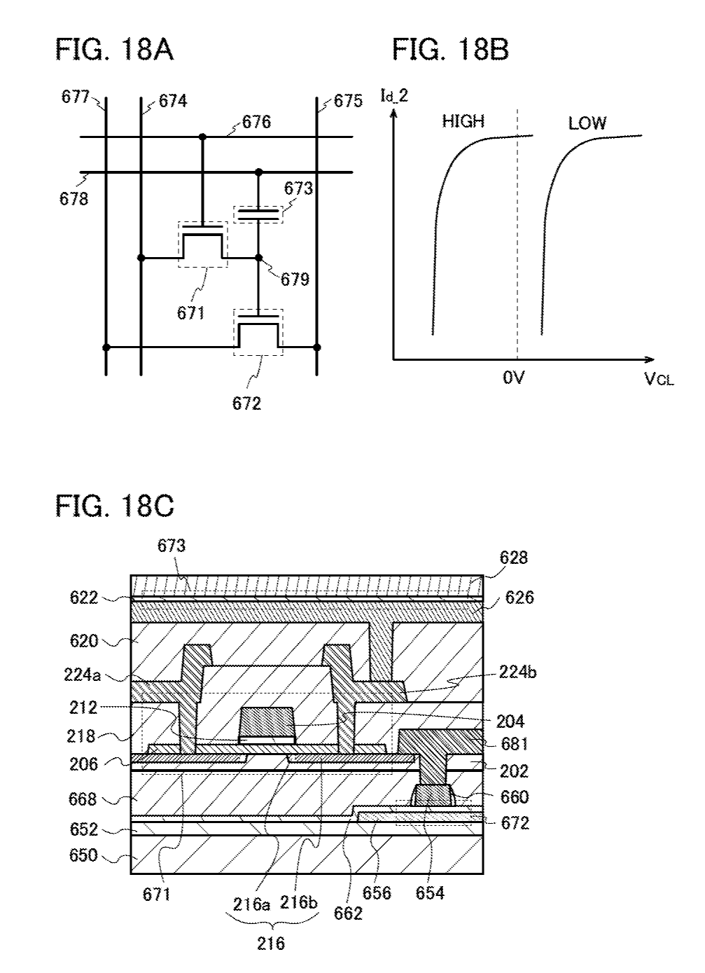

Next, a semiconductor device having a structure different from that in FIGS. 17A to 17D will be described with reference to FIGS. 18A to 18C. FIG. 18A is a circuit diagram showing a memory cell and wirings included in the semiconductor device. FIG. 18B is a graph showing electric characteristics of the memory cell in FIG. 18A. FIG. 18C is an example of a cross-sectional view corresponding to the memory cell in FIG. 18A.

As shown in FIG. 18A, the memory cell includes a transistor 671, a transistor 672, and a capacitor 673. Here, a gate of the transistor 671 is electrically connected to a word line 676. A source of the transistor 671 is electrically connected to a source line 674. A drain of the transistor 671 is electrically connected to a gate of the transistor 672 and one terminal of the capacitor 673. A portion where the drain of the transistor 671 is electrically connected to the gate of the transistor 672 and the one terminal of the capacitor 673 is referred to as a node 679. A source of the transistor 672 is electrically connected to a source line 675. A drain of the transistor 672 is electrically connected to a drain line 677. The other terminal of the capacitor 673 is electrically connected to a capacitor line 678.

The semiconductor device illustrated in FIGS. 18A to 18C utilizes variation in the apparent threshold voltage of the transistor 672, which depends on the potential of the node 679. For example, FIG. 18B shows a relation between a voltage W_{I}, of the capacitor line 678 and a drain current I_{d}_{_{—}}2 flowing through the transistor 672.

The potential of the node 679 can be controlled through the transistor 671. For example, the potential of the source line 674 is set to a power supply potential VDD. In this case, when the potential of the word line 676 is set to be higher than or equal to a potential obtained by adding the power supply potential VDD to the threshold voltage Vth of the transistor 671, the potential of the node 679 can be HIGH. Further, when the potential of the word line 676 is set to be lower than or equal to the threshold voltage Vth of the transistor 671, the potential of the node 679 can be LOW.

Thus, the transistor 672 has electric characteristics shown with either a V_{CL}-I_{d}_{_{—}}2 curve denoted as LOW or a V_{CL}-I_{d}_{₂} curve denoted as HIGH. That is, when the potential of the node 679 is LOW, I_{d}_{_{—}}2 is small at a V_{CL} of 0 V; accordingly, data 0 is stored. Further, when the potential of the node 679 is HIGH, I_{d}_{_{—}}2 is large at a V_{CL} of 0 V; accordingly, data 1 is stored. In such a manner, data can be stored.

FIG. 18C illustrates an example of a cross-sectional structure of the memory cell. FIG. 18C is a cross-sectional view of the semiconductor device including the transistor 672; an insulating film 668 over the transistor 672; the transistor 671 over the insulating film 668; the wirings 224a and 224b connected to the transistor 671; an insulating film 620 over the transistor 671 and the wirings 224a and 224b; and the capacitor 673 over the insulating film 620.

The insulating film 620 may be formed of a single layer or a stacked layer using an insulating film containing one or more of aluminum oxide, magnesium oxide, silicon oxide, silicon oxynitride, silicon nitride oxide, silicon nitride, germanium oxide, yttrium oxide, zirconium oxide, lanthanum oxide, neodymium oxide, hafnium oxide, and tantalum oxide. Alternatively, a resin film of a polyimide resin, an acrylic resin, an epoxy resin, a silicone resin, or the like may be used as the insulating film 620.

In FIG. 18C, the transistor illustrated in FIGS. 2A to 2C is used as the transistor 671. Therefore, for components of the transistor 671 which are not particularly described below, refer to the description in the above embodiment. The case where an oxide semiconductor film is used as the semiconductor film 206 in the transistor 671 is described below.

In this embodiment, the case where a transistor including crystalline silicon is used as the transistor 672 will be described. Note that any of the transistors described in the above embodiment may be used as the transistor 672.

The transistor including crystalline silicon has an advantage that on-state characteristics can be improved more easily than a transistor including an oxide semiconductor film. Therefore, it can be said that the transistor including crystalline silicon is suitable for the transistor 672 for which excellent on-state characteristics are required.

Here, the transistor 672 includes a base insulating film 652 over a substrate 650; a crystalline silicon film 656 over the base insulating film 652; a gate insulating film 662 over the crystalline silicon film 656; a gate electrode 654 overlapping with the crystalline silicon film 656, over the gate insulating film 662; and sidewall insulating films 660 in contact with sidewalls of the gate electrode 654.

As the substrate 650, a substrate similar to the substrate 100 may be used.

As the base insulating film 652, an insulating film similar to the base insulating film 102 may be used.

As the crystalline silicon film 656, a silicon film such as a single crystal silicon film or a polycrystalline silicon film may be used.

Note that the crystalline silicon film is used in the transistor 672 in this embodiment; however, in the case where the substrate 650 is a semiconductor substrate such as a silicon wafer, a channel region and source and drain regions may be provided in the semiconductor substrate in the transistor 672.

The gate insulating film 662 may be formed of a single layer or a stacked layer using an insulating film containing one or more of aluminum oxide, magnesium oxide, silicon oxide, silicon oxynitride, silicon nitride oxide, silicon nitride, germanium oxide, yttrium oxide, zirconium oxide, lanthanum oxide, neodymium oxide, hafnium oxide, and tantalum oxide.

As the gate electrode 654, a conductive film similar to the gate electrode 104 may be used.

The sidewall insulating films 660 may be formed of a single layer or a stacked layer using an insulating film containing one or more of aluminum oxide, magnesium oxide, silicon oxide, silicon oxynitride, silicon nitride oxide, silicon nitride, germanium oxide, yttrium oxide, zirconium oxide, lanthanum oxide, neodymium oxide, hafnium oxide, and tantalum oxide.

The insulating film 668 may be formed of a single layer or a stacked layer using an insulating film containing one or more of aluminum oxide, magnesium oxide, silicon oxide, silicon oxynitride, silicon nitride oxide, silicon nitride, germanium oxide, yttrium oxide, zirconium oxide, lanthanum oxide, neodymium oxide, hafnium oxide, and tantalum oxide. Alternatively, a resin film of a polyimide resin, an acrylic resin, an epoxy resin, a silicone resin, or the like may be used as the insulating film 668.

An opening reaching the gate electrode 654 of the transistor 672 is provided in the insulating film 668 and the base insulating film 202. One of the pair of semiconductor layers 216 of the transistor 671 is electrically connected to the gate electrode 654 of the transistor 672 through a conductive film 681 provided in the opening.

The conductive film 681 may be formed of a single layer or a stacked layer using one or more conductive films containing a simple substance selected from Al, Ti, Cr, Co, Ni, Cu, Y, Zr, Mo, Ag, Ta, and W; a nitride containing one or more kinds of the above substances; an oxide containing one or more kinds of the above substances; or an alloy containing one or more kinds of the above substances.

The capacitor 673 includes an electrode 626 in contact with the wiring 224b; an electrode 628 overlapping with the electrode 626; and an insulating film 622 sandwiched between the electrode 626 and the electrode 628.

As the electrode 626, a conductive film similar to the electrode 526 may be used.

As the electrode 628, a conductive film similar to the electrode 528 may be used.

Here, the wiring 224a in FIG. 18C is electrically connected to the source line 674 in FIG. 18A. The gate electrode 604 in FIG. 18C is electrically connected to the word line 676 in FIG. 18A. The electrode 628 in FIG. 18C is electrically connected to the capacitor line 678 in FIG. 18A.

In the example of FIG. 18C, the transistor 671 and the capacitor 673 are provided in different layers so as to overlap with each other; however, one embodiment of the present invention is not limited to this structure. For example, the transistor 671 and the capacitor 673 may be provided in the same layer. With such a structure, memory cells having similar structures can be disposed so as to overlap with each other, in which case, a large number of memory cells can be integrated in an area for one memory cell. Accordingly, the degree of integration of the semiconductor device can be improved.

Here, with the use of the transistor including an oxide semiconductor film in the above embodiment as the transistor 671, a charge accumulated in the node 679 can be prevented from leaking through the transistor 671 because the off-state current of the transistor is extremely small. Therefore, data can be held for a long period. Further, a voltage for writing data does not need to be high as compared to the case of a flash memory; thus, power consumption can be made lower and operation speed can be made higher.

As described above, according to one embodiment of the present invention, a semiconductor device with high degree of integration and low power consumption can be provided.

The parasitic resistance of each of the transistors described in the above embodiment is low and the parasitic capacitance thereof is small. Therefore, the operation speed of a semiconductor device including the transistor can be improved.

This embodiment is obtained by performing change, addition, modification, removal, application, superordinate conceptualization, or subordinate conceptualization on part or the whole of another embodiment. Thus, part or the whole of this embodiment can be freely combined with, applied to, or replaced with part or the whole of another embodiment.

### Embodiment 5

A central processing unit (CPU) can be formed using any of the transistors and the semiconductor devices described in any of the above embodiments for at least part of the CPU.

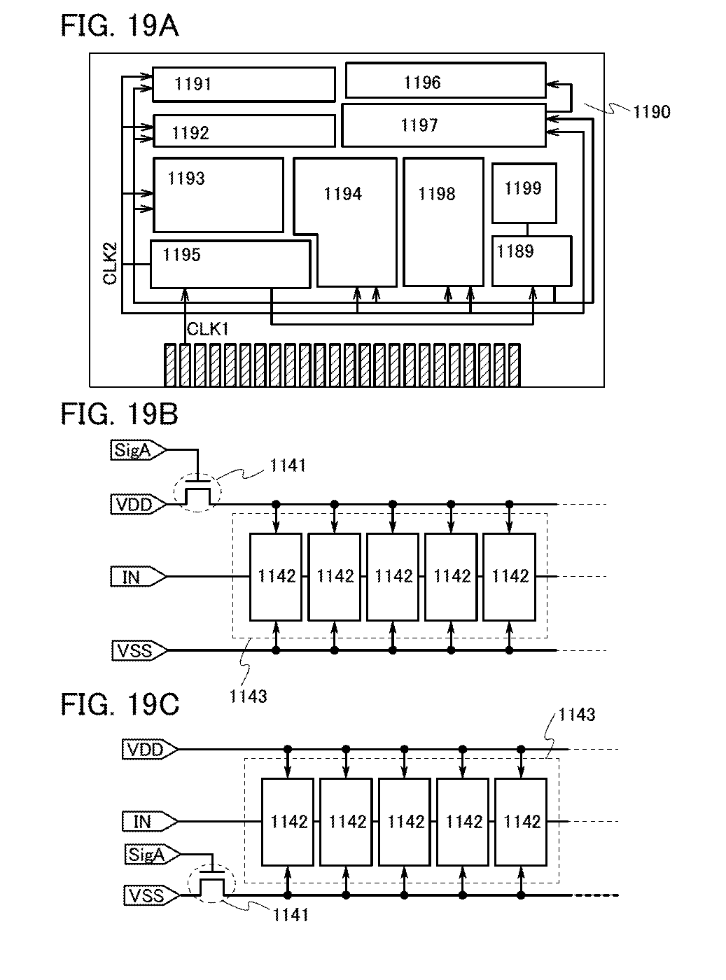

FIG. 19A is a block diagram illustrating a specific structure of the CPU. The CPU illustrated in FIG. 19A includes an arithmetic logic unit (ALU) 1191, an ALU controller 1192, an instruction decoder 1193, an interrupt controller 1194, a timing controller 1195, a register 1196, a register controller 1197, a bus interface (Bus I/F) 1198, a rewritable ROM 1199, and a ROM interface (ROM I/F) 1189 over a substrate 1190. A semiconductor substrate, an SOI substrate, a glass substrate, or the like is used as the substrate 1190. The ROM 1199 and the ROM interface 1189 may be provided over a separate chip. Obviously, the CPU shown in FIG. 19A is just an example in which the configuration has been simplified, and an actual CPU may have various configurations depending on the application.

An instruction that is input to the CPU through the bus interface 1198 is input to the instruction decoder 1193 and decoded therein, and then, input to the ALU controller 1192, the interrupt controller 1194, the register controller 1197, and the timing controller 1195.

The ALU controller 1192, the interrupt controller 1194, the register controller 1197, and the timing controller 1195 conduct various controls in accordance with the decoded instruction. Specifically, the ALU controller 1192 generates signals for controlling the operation of the ALU 1191. While the CPU is executing a program, the interrupt controller 1194 determines an interrupt request from an external input/output device or a peripheral circuit on the basis of its priority or a mask state, and processes the request. The register controller 1197 generates an address of the register 1196, and reads/writes data from/to the register 1196 in accordance with the state of the CPU.

The timing controller 1195 generates signals for controlling operation timings of the ALU 1191, the ALU controller 1192, the instruction decoder 1193, the interrupt controller 1194, and the register controller 1197. For example, the timing controller 1195 includes an internal clock generator for generating an internal clock signal CLK2 based on a reference clock signal CLK1, and supplies the clock signal CLK2 to the above circuits.

In the CPU illustrated in FIG. 19A, a memory element is provided in the register 1196. For the register 1196, any of the semiconductor devices described in the above embodiment can be used.

In the CPU illustrated in FIG. 19A, the register controller 1197 selects operation of retaining data in the register 1196 in accordance with an instruction from the ALU 1191. That is, the register controller 1197 selects whether data is retained by a flip-flop or a capacitor in the memory element included in the register 1196. When data is retained by the flip-flop, a power supply voltage is supplied to the memory element in the register 1196. When data is retained by the capacitor, the data in the capacitor is rewritten, and supply of the power supply voltage to the memory element in the register 1196 can be stopped.

A switching element provided between a memory element group and a node to which a power supply potential VDD or a power supply potential VSS is supplied, as illustrated in FIG. 19B or FIG. 19C, allows the power supply voltage to be stopped. Circuits illustrated in FIGS. 19B and 19C will be described below.

FIGS. 19B and 19C each illustrate an example of a structure including any of the transistors described in the above embodiment as a switching element for controlling supply of a power supply potential to a memory element.

The memory device illustrated in FIG. 19B includes a switching element 1141 and a memory element group 1143 including a plurality of memory elements 1142. Specifically, as each of the memory elements 1142, the semiconductor device described in the above embodiment can be used. Each of the memory elements 1142 included in the memory element group 1143 is supplied with the high-level power supply potential VDD through the switching element 1141. Further, each of the memory elements 1142 included in the memory element group 1143 is supplied with a potential of a signal IN and a potential of the low-level power supply potential VSS.

In FIG. 19B, as the switching element 1141, the transistor described in the above embodiment is used. With the use of an oxide semiconductor as the semiconductor film in the transistor, the off-state current of the transistor can be made extremely small. The switching of the transistor is controlled by a signal SigA input to a gate thereof.

Note that FIG. 19B illustrates the structure in which the switching element 1141 includes only one transistor; however, one embodiment of the present invention is not limited thereto. The switching element 1141 may include a plurality of transistors. In the case where the switching element 1141 includes a plurality of transistors which serves as switching elements, the plurality of transistors may be connected to each other in parallel, in series, or in combination of parallel connection and series connection.

In FIG. 19C, an example of a memory device in which each of the memory elements 1142 included in the memory element group 1143 is supplied with the low-level power supply potential VSS through the switching element 1141 is illustrated. The supply of the low-level power supply potential VSS to each of the memory elements 1142 included in the memory element group 1143 can be controlled by the switching element 1141.

When a switching element is provided between a memory element group and a node to which the power supply potential VDD or the power supply potential VSS is supplied, data can be retained even in the case where an operation of a CPU is temporarily stopped and the supply of the power supply voltage is stopped; accordingly, power consumption can be reduced. For example, while a user of a personal computer does not input data to an input device such as a keyboard, the operation of the CPU can be stopped, so that the power consumption can be reduced.

Although the CPU is given as an example, the transistor and the semiconductor memory device can also be applied to an LSI such as a digital signal processor (DSP), a custom LSI, or a field programmable gate array (FPGA).

This embodiment is obtained by performing change, addition, modification, removal, application, superordinate conceptualization, or subordinate conceptualization on part or the whole of another embodiment. Thus, part or the whole of this embodiment can be freely combined with, applied to, or replaced with part or the whole of another embodiment.

### Embodiment 6

In this embodiment, examples of an electronic device to which any of the semiconductor devices described in the above embodiment is applied will be described.

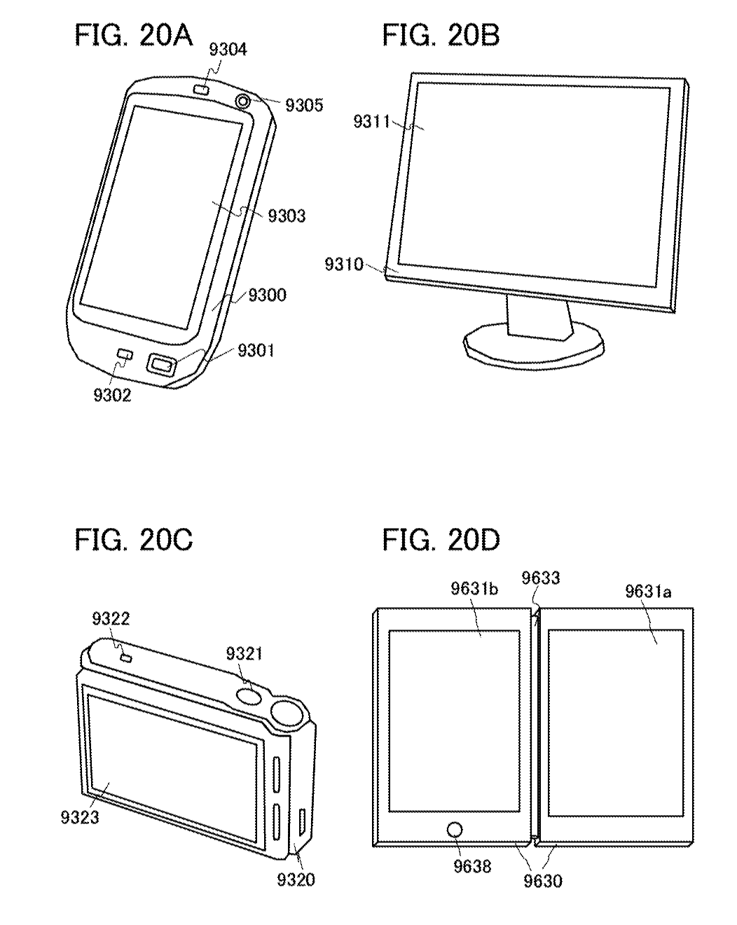

FIG. 20A illustrates a portable information terminal. The portable information terminal illustrated in FIG. 20A includes a housing 9300, a button 9301, a microphone 9302, a display portion 9303, a speaker 9304, and a camera 9305, and has a function as a mobile phone. One embodiment of the present invention can be applied to an arithmetic unit, a wireless circuit, or a memory circuit in a main body. One embodiment of the present invention can also be applied to the display portion 9303.

FIG. 20B illustrates a display, which includes a housing 9310 and a display portion 9311. One embodiment of the present invention can be applied to an arithmetic unit, a wireless circuit, or a memory circuit in a main body. One embodiment of the present invention can also be applied to the display portion 9311.

FIG. 20C illustrates a digital still camera. The digital still camera illustrated in FIG. 20C includes a housing 9320, a button 9321, a microphone 9322, and a display portion 9323. One embodiment of the present invention can be applied to an arithmetic unit, a wireless circuit, or a memory circuit in a main body. One embodiment of the present invention can also be applied to the display portion 9323.

FIG. 20D illustrates a double-foldable portable information terminal. The double-foldable portable information terminal illustrated in FIG. 20D includes a housing 9630, a display portion 9631a, a display portion 9631b, a hinge 9633, and an operation switch 9638. One embodiment of the present invention can be applied to an arithmetic unit, a wireless circuit, or a memory circuit in a main body. One embodiment of the present invention can also be applied to the display portion 9631a and the display portion 9631b.

Part or the whole of the display portion 9631a and/or the display portion 9631b can function as a touch panel. By touching an operation key displayed on the touch panel, a user can input data, for example.

With the use of a semiconductor device according to one embodiment of the present invention, an electronic device with high reliability, high performance, and low power consumption can be provided.

This embodiment is obtained by performing change, addition, modification, removal, application, superordinate conceptualization, or subordinate conceptualization on part or the whole of another embodiment. Thus, part or the whole of this embodiment can be freely combined with, applied to, or replaced with part or the whole of another embodiment.

Note that, in this specification and the like, part of a diagram or a text described in one embodiment can be taken out to constitute one embodiment of the invention. Thus, in the case where a diagram or a text related to a certain part is described, a content taken out from a diagram or a text of the certain part is also disclosed as one embodiment of the invention and can constitute one embodiment of the invention. Therefore, for example, part of a diagram or a text including one or more of active elements (e.g., transistors or diodes), wirings, passive elements (e.g., capacitors or resistors), conductive layers, insulating layers, semiconductor layers, organic materials, inorganic materials, components, devices, operating methods, manufacturing methods, or the like can be taken out to constitute one embodiment of the invention. For example, M circuit elements (e.g., transistors or capacitors) (M is an integer) are picked up from a circuit diagram in which N circuit elements (e.g., transistors or capacitors) (N is an integer, where M<N) are provided, whereby one embodiment of the invention can be constituted. As another example, M layers (M is an integer) are picked up from a cross-sectional view in which N layers (N is an integer, where M<N) are provided, whereby one embodiment of the invention can be constituted. As another example, M elements (M is an integer) are picked up from a flow chart in which N elements (N is an integer, where M<N) are provided, whereby one embodiment of the invention can be constituted.

Note that, in the case where at least one specific example is described in a diagram or a text described in one embodiment in this specification and the like, it will be readily appreciated by those skilled in the art that a broader concept of the specific example can be derived. Therefore, in the diagram or the text described in one embodiment, in the case where at least one specific example is described, a broader concept of the specific example is disclosed as one embodiment of the invention and can constitute one embodiment of the invention.

Note that, in this specification and the like, a content described in at least a diagram (which may be part of the diagram) is disclosed as one embodiment of the invention and can constitute one embodiment of the invention. Therefore, when a certain content is described in a diagram, the content is disclosed as one embodiment of the invention even without text description and can constitute one embodiment of the invention. Similarly, a diagram obtained by taking out part of a diagram is disclosed as one embodiment of the invention and can constitute one embodiment of the invention.

This application is based on Japanese Patent Application serial no. 2012-056798 filed with Japan Patent Office on Mar. 14, 2012, the entire contents of which are hereby incorporated by reference.

What is claimed is:

1. A semiconductor device comprising:
a pair of semiconductor layers;
a semiconductor film in contact with each of the pair of semiconductor layers;
a gate electrode overlapping with the semiconductor film, the gate electrode at least partly overlapping with the pair of semiconductor layers; and
a gate insulating film between the semiconductor film and the gate electrode,
wherein the pair of semiconductor layers each have a first region overlapping with the gate electrode and the semiconductor film and a second region having lower resistance than the first region.

2. The semiconductor device according to claim 1,
wherein the gate electrode is located over the semiconductor film.

3. The semiconductor device according to claim 1, further comprising:
a first electrode electrically connected to one of the pair of semiconductor layers; and
a display element over the first electrode.

4. The semiconductor device according to claim 3, further comprising:
a second electrode existing in the same layer as the one of the pair of semiconductor layers,
wherein the second electrode at least partly overlaps with the first electrode with an insulating film between the second electrode and the first electrode.

5. The semiconductor device according to claim 1,
wherein each of the pair of semiconductor layers is in contact with a bottom surface of the semiconductor film.

6. The semiconductor device according to claim 1,
wherein each of the pair of semiconductor layers is in contact with a top surface of the semiconductor film.

7. The semiconductor device according to claim 1,
wherein the second region contains an impurity generating a carrier in the pair of semiconductor layers.

8. The semiconductor device according to claim 1, further comprising a sidewall insulating film in contact with a side surface of the gate electrode.

9. The semiconductor device according to claim 1,
wherein each of the pair of semiconductor layers contains silicon, germanium, zinc oxide, indium oxide, or tin oxide.

10. The semiconductor device according to claim 1,
wherein the semiconductor film is an oxide semiconductor film.

11. The semiconductor device according to claim 10,
wherein the oxide semiconductor film contains at least indium.

12. A method for manufacturing a semiconductor device, comprising the steps of:
forming a pair of semiconductor layers;
forming a semiconductor film over the pair of semiconductor layers;
forming a gate insulating film over the semiconductor film;
forming a gate electrode over the gate insulating film; and
performing treatment for reducing a resistance of a region which is in the pair of semiconductor layers and does not overlap with the gate electrode, using the gate electrode as a mask.

13. The method for manufacturing a semiconductor device, according to claim 12, further comprising the steps of:
after the step of performing the treatment for reducing the resistance, forming a sidewall insulating film on a side surface of the gate electrode; and
adding an impurity generating a carrier in the pair of semiconductor layers to a region which is in the pair of semiconductor layers and overlaps with neither the gate electrode nor the sidewall insulating film, using the gate electrode and the sidewall insulating film as masks.

14. The method for manufacturing a semiconductor device, according to claim 12,
wherein, as the treatment for reducing the resistance, an impurity generating a carrier in the pair of semiconductor layers is added to the region.

15. The method for manufacturing a semiconductor device, according to claim 12,
wherein each of the pair of semiconductor layers contains silicon, germanium, zinc oxide, indium oxide, or tin oxide.

16. The method for manufacturing a semiconductor device, according to claim 12,
wherein the semiconductor film is an oxide semiconductor film.

17. A method for manufacturing a semiconductor device, comprising the steps of:
forming a semiconductor film;
forming a pair of semiconductor layers over the semiconductor film;
forming a gate insulating film over the semiconductor film and the pair of semiconductor layers;
forming a gate electrode over the gate insulating film; and
performing treatment for reducing a resistance of a region which is in the pair of semiconductor layers and does not overlap with the gate electrode, using the gate electrode as a mask.

18. The method for manufacturing a semiconductor device, according to claim 17, further comprising the steps of:
after the step of performing the treatment for reducing the resistance, forming a sidewall insulating film on a side surface of the gate electrode; and
adding an impurity generating a carrier in the pair of semiconductor layers to a region which is in the pair of semiconductor layers and overlaps with neither the gate electrode nor the sidewall insulating film, using the gate electrode and the sidewall insulating film as masks.

19. The method for manufacturing a semiconductor device, according to claim 17,
wherein, as the treatment for reducing the resistance, an impurity generating a carrier in the pair of semiconductor layers is added to the region.

20. The method for manufacturing a semiconductor device, according to claim 17,
wherein each of the pair of semiconductor layers contains silicon, germanium, zinc oxide, indium oxide, or tin oxide.

21. The method for manufacturing a semiconductor device, according to claim 17,
wherein the semiconductor film is an oxide semiconductor film.
